(19) United States
(12) Patent Application Publication
(10) Pub. No.: US 2025/0006572 A1
(43) Pub. Date: Jan. 2, 2025

(54) PACKAGE STRUCTURE INCLUDING RING STRUCTURE AND METHODS OF FORMING THE SAME

(71) Applicant: Taiwan Semiconductor Manufacturing Company Limited, Hsinchu (TW)

(72) Inventors: Hsien-Wei Chen, Hsinchu City (TW); Meng-Liang Lin, Hsinchu (TW); Ying-Ju Chen, Tuku Township (TW); Shin-Puu Jeng, Po-Shan Village (TW)

(21) Appl. No.: 18/343,801

(22) Filed: Jun. 29, 2023

(51) Int. Cl. H01L 23/16; H01L 21/50; H01L 23/00; H01L 23/31; H01L 23/367; H01L 23/498; H01L 25/065

(52) U.S. Cl. CPC H01L 23/16; H01L 21/50; H01L 23/3107; H01L 23/367; H01L 23/49822; H01L 24/16; H01L 24/32; H01L 24/73; H01L 25/0655; H01L 2224/16227; H01L 2224/16238; H01L 2224/32225; H01L 2224/32245; H01L 2224/73204; H01L 2224/73253; H01L 2924/16235; H01L 2924/16251

(57) ABSTRACT

A package structure includes a package substrate, a semiconductor die module on the package substrate, a first adhesive and a second adhesive on the package structure, wherein the second adhesive is between the first adhesive and the semiconductor die module, and a ring structure on the package substrate around the semiconductor die module, wherein the ring structure includes an outer ring attached to the package substrate by the first adhesive, and an inner ring between the semiconductor die module and the outer ring and attached to the package substrate by the second adhesive.

### BACKGROUND

A package structure (e.g., semiconductor package) may house and protect one or more semiconductor dies (e.g., chips). The package structure may be subject to various stresses and strains during the manufacturing process, as well as during handling, assembly, and operation. For example, thermal cycling during the manufacturing process may cause the package structure to heat and cool. This thermal cycling and the differences in thermal coefficients of expansion for the various materials used in the package structure may cause significant stress and strain on the package structure. These stresses may cause the package structure to deform, which may result in various types of failures, such as cracking or delamination of the package materials, or damage to the semiconductor dies.

The package structure may include a stiffener ring to provide mechanical support and increase the overall structural integrity of the package structure. The stiffener ring may be made of a rigid material, such as metal or ceramic. The stiffener ring may be placed around a periphery of the semiconductor chips. It may be designed to provide additional mechanical support to the package, particularly at the edges where stresses are most likely to occur. The stiffener ring may help to distribute stresses evenly across the package, may mitigate against deformation and damage to the package and its contents. The stiffener ring may thereby increase the reliability of the package structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure (e.g., organic/silicon interposer package) according to one or more embodiments.

FIG. 1B is a plan view (e.g., top-down view) of the package structure according to one or more embodiments.

FIG. 1C is a detailed vertical cross-sectional view of the ring structure and adhesive according to one or more embodiments.

FIG. 2A is a plan view (e.g., top-down view) of an intermediate structure including a metal sheet, according to one or more embodiments.

FIG. 2B is a plan view (e.g., top-down view) of an intermediate structure including a metal sheet having a frame shape, according to one or more embodiments.

FIG. 2C is a plan view (e.g., top-down view) of an intermediate structure including a metal sheet having a frame shape, according to one or more embodiments.

FIG. 2D is a plan view (e.g., top-down view) of an intermediate structure including the ring structure having the outer ring and the inner ring, according to one or more embodiments.

FIG. 3A is a vertical cross-sectional view of an intermediate structure including a portion of the interposer (e.g., organic interposer) formed on a first carrier substrate (e.g., carrier wafer) according to an embodiment of the present invention.

FIG. 3B is a vertical cross-sectional view of an intermediate structure including the first semiconductor die and second semiconductor die, according to one or more embodiments.

FIG. 3C is a vertical cross-sectional view of an intermediate structure including the interposer underfill layer according to one or more embodiments.

FIG. 3D is a vertical cross-sectional view of an intermediate structure including the molding material layer, according to one or more embodiments

FIG. 3E illustrates a vertical cross-sectional view of an intermediate structure including the plurality of C4 bumps, according to one or more embodiments.

FIG. 4A is a vertical cross-sectional view of an intermediate structure including the package substrate having package substrate upper bonding pads and package substrate lower bonding pads, according to one or more embodiments.

FIG. 4B illustrates a vertical cross-sectional view of an intermediate structure in which the semiconductor die module may be mounted on the package substrate, according to one or more embodiments.

FIG. 4C illustrates a vertical cross-sectional view of an intermediate structure in which the package underfill layer may be formed on the package substrate according to one or more embodiments.

FIG. 4D illustrates a vertical cross-sectional view of an intermediate structure in which the adhesive may be applied to the package substrate according to one or more embodiments.

FIG. 4E illustrates a vertical cross-sectional view of an intermediate structure in which the ring structure may be attached to (e.g., mounted on) the package substrate according to one or more embodiments.

FIG. 4F illustrates a vertical cross-sectional view of an intermediate structure in which a plurality of solder balls may be formed on the package substrate according to one or more embodiments.

FIG. 5 is a flow chart illustrating a method of making the package structure according to one or more embodiments.

FIG. 6 is a vertical cross-sectional view of the package structure having a first alternative design according to one or more embodiments.

FIG. 7 is a plan view (top down view) of the package structure having a second alternative design according to one or more embodiments.

FIG. 8 is a vertical cross-sectional view of the package structure having a third alternative design according to one or more embodiments.

FIG. 9 is a vertical cross-sectional view of the package structure having a fourth alternative design according to one or more embodiments

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A stiffener ring (e.g., ring component) may include a copper ring and may be attached to a package substrate by an adhesive. However, the process window for using the stiffener ring in a package structure may be limited by corner/peripheral high co-planarity (COP) (e.g., high corner warpage and ball grid array (BGA) joint issue). The process window may also be limited by high die-to-die underfill (D2D UF1) stress and delamination by a standard ring attachment approach. These limitations may be due to a trade-off between coefficient of thermal expansion (CTE) mismatching near a chip-on-wafer area and a corner edge of the package substrate.

One or more embodiments of the present disclosure may help to mitigate against these limitations. In particular, the one or more embodiments may provide alongside rings to control warpage and/or stress in between a package substrate corner edge and a middle chip-on-wafer area in the package structure. By providing collaborated warpage control the embodiments may mitigate against package joint and CTE mismatch stress reliability issue. The various embodiments disclosed herein may also provide a flexible design for warpage management and a multi-chip module (MCM) application.

One or more embodiments disclosed herein may include an alongside heat sink structure. At least one embodiment may include a heat sink/ring component stacking package. The various embodiments disclosed herein may enable collaborated warpage control in between corner edge of the package substrate and middle chip-on-wafer area. This may help mitigate against package joint (e.g., BGA joint) issue and CTE mismatch stress reliability issue in the package structure.

In contrast to package structures that may include a single ring or vertical-stacked (e.g., AB ring) on the package substrate, one or more embodiments disclosed herein may provide an alongside ring attachment (e.g., horizontal ring attachment; lateral ring attachment) on the package substrate.

One or more embodiments may include a package structure including a package substrate, a semiconductor die module (e.g., chip-on-wafer module) on the package substrate, and a BGA or land grid array (LGA) on the package substrate. In at least one embodiment, the semiconductor die module may include one or more system-on-chip (SOC) dies and one or more high bandwidth memory (HBM) dies.

The various embodiments disclosed herein may also include a plurality of ring components (e.g., copper, alloy, welded metal, etc.) on the package substrate. The ring components may be attached to the package substrate by an adhesive. The ring components may include horizontal alongside ring components. The ring components may be located at a periphery of the package substrate.

The plurality of ring components may include an outer ring (e.g., outermost ring) and an inner ring (e.g., innermost ring). In addition to providing mechanical support, the inner ring can also help to improve the thermal performance of the package structure. By increasing the surface area of the package structure, the inner ring may improve heat dissipation and help to maintain a more uniform temperature across the package structure. This may be desirable for use in high-power semiconductor devices, which may generate large amounts of heat during operation.

The outer ring may have a thickness H1 given as 0.1 mm≤H1≤10 mm and a width (e.g., lateral width) W1 given as 0.5 mm≤W1≤10 mm. The outer ring may also have a coefficient of thermal expansion C1 given as 3 ppm/C≤C1≤20 ppm/C.

The inner ring may be formed laterally adjacent to the outer ring. The inner ring may have a thickness H2, a width W2 and a coefficient of thermal expansion C2. A thickness ratio H2/H1 of the ring components may be given as 0.5≤H2/H1≤1. The semiconductor die module may have a thickness H₁₂₀, and a thickness ratio H2/H₁₂₀ may be in a range from 1 to 3.

A width ratio W2/W1 of the ring components may be given as 0.8≤W2/W1≤1.2. In at least one embodiment, W2 may be greater than W1. A CTE ratio C2/C1 of the ring components may be given as 0.2≤C2/C1≤5. In at least one embodiment, C2 may be greater than C1. A space between the outer ring and the inner ring may have a width W3 given as 0≤W3≤3 mm.

In at least one embodiment, the package structure may include a package lid (e.g., one or more lid components). The package lid may be mounted on the outer ring and cover the semiconductor die module. A thermal interface material (TIM) layer may be located between the package lid and the semiconductor die module. An upper surface of the inner ring may be separated from a bottom surface of the package lid.

In at least one embodiment, the outer ring may include a material that is different from a material of the inner ring. In particular, the outer ring may include copper and the inner ring may include an iron-nickel alloy (Alloy 42).

In at least one embodiment, the outer ring may have a square shape and a first side having a first width and a second side having a second width greater than the first width. The inner ring may also have a square shape and a first side having a first width and a second side having a second width greater than the first width. The arrangement of the first side and second side in each of the outer ring and inner ring may depend on a configuration of the semiconductor die module. In particular, the second side of both the outer ring and inner ring may be located along a longitudinal side of the semiconductor die module.

A distance between the inner ring and the semiconductor die module may be in a range from 1 mm to 5 mm. In at least one embodiment, the distance may be about 3 mm. The distance between the inner ring and the semiconductor die module may be uniform around the semiconductor die module or may vary within the range of 1 mm to 5 mm.

A distance between the inner ring and the outer ring may range from greater than zero to 3 mm. The distance may be uniform around the inner ring or may vary within the range from greater than zero to 3 mm. In at least one embodiment, an inner sidewall of the outer ring may contact an outer side wall of the inner ring so that no space is formed between the outer ring and inner ring.

There may be a distance between the outer ring and an edge of the package substrate in order to allow for adhesive overflow. The distance may be in a range from 0.1 mm to 1.0 mm. In at least one embodiment, the distance may be about 0.2 mm.

A first adhesive may fix outer ring to the package substrate, and a second adhesive may fix the inner ring to the package substrate. The first adhesive may be substantially the same as the second adhesive. In at least one embodiment, the first adhesive may be different from the second adhesive. In at least one embodiment, each of the first adhesive and the second adhesive may have Young's modulus in a range from 0.1 GPa to 10 GPa.

In at least one embodiment the semiconductor die module may have a long side and a short side. In such embodiments, the semiconductor die module may have a particular arrangement relative to the width W1 of outer ring and the width W2 of inner ring. In particular, the long side of the semiconductor die module may be located along a large width side of the inner ring and a short side of the semiconductor die module may be located along a small width side of the inner ring. This arrangement may help to manage a package warpage behavior in a direction of the long side of the semiconductor die module and a direction of the short side of the semiconductor die module. This may be especially helpful in the case of asymmetric packaging (e.g., where a shape of the semiconductor die module is different from a shape of the package substrate). In particular, the large width side of the inner ring may be used to control package warpage in a direction of the short side of the semiconductor die module, especially in a case of asymmetric packaging.

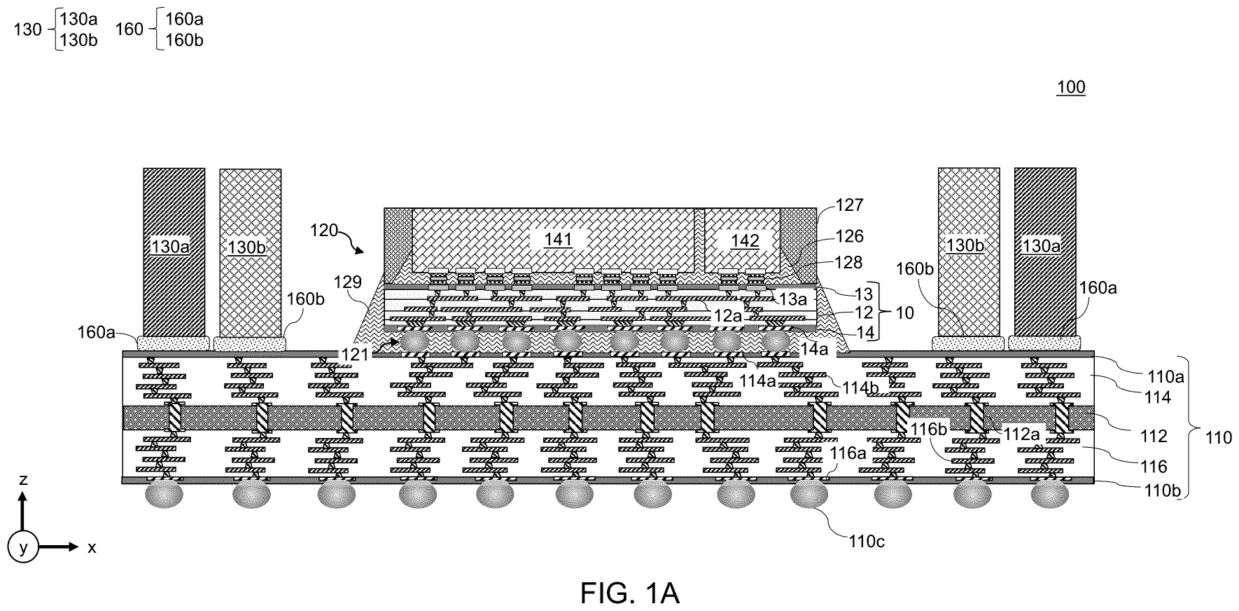

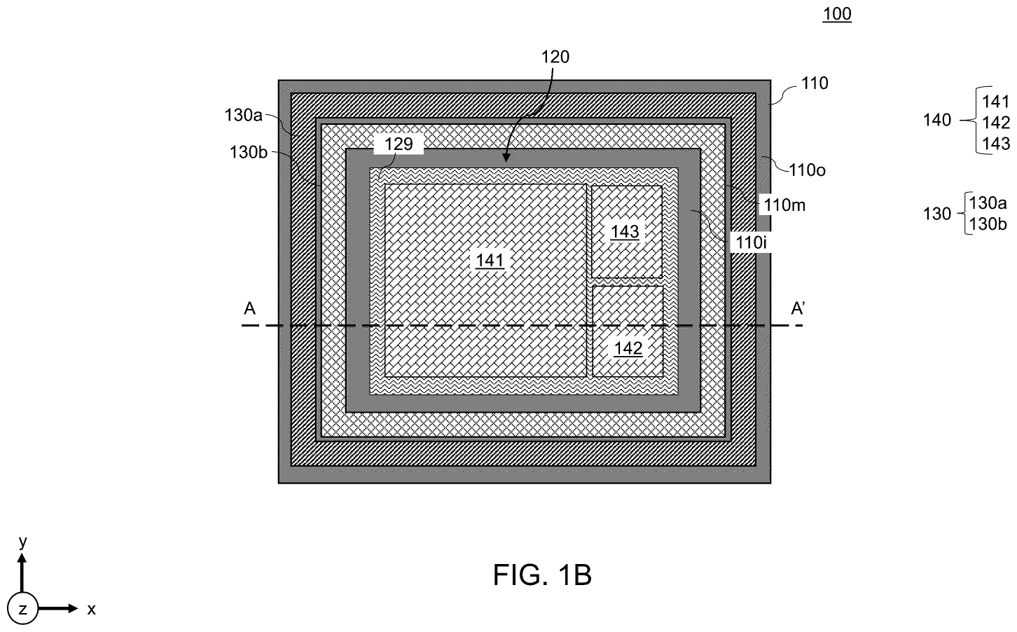

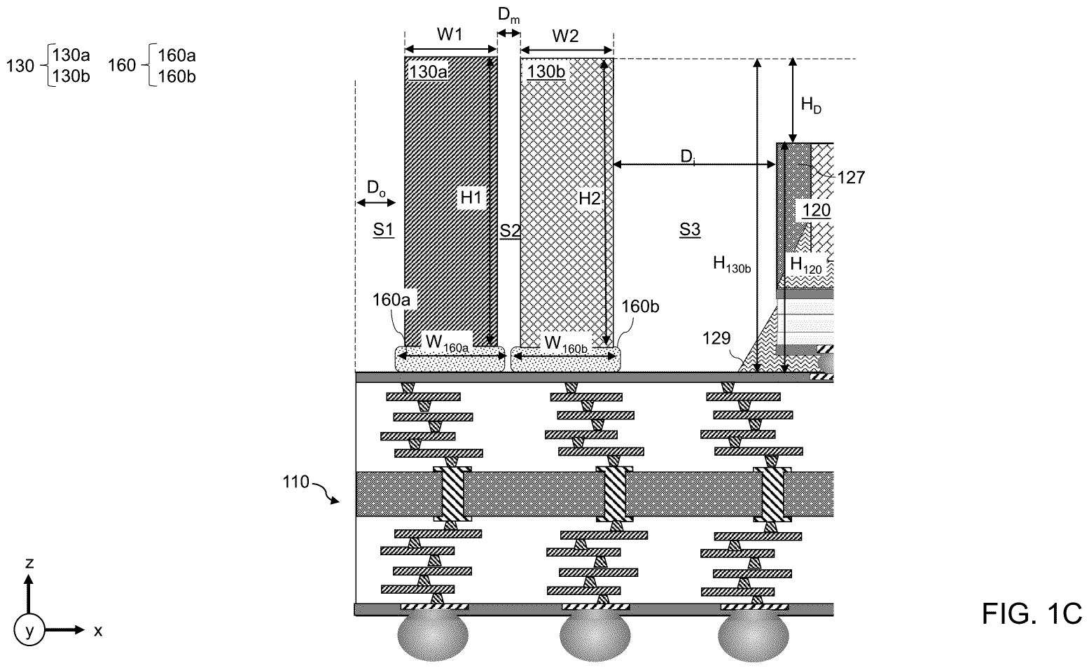

FIG. 1A is a vertical cross-sectional view of a package structure 100 (e.g., organic/silicon interposer package) according to one or more embodiments. FIG. 1B is a plan view (e.g., top-down view) of the package structure 100 according to one or more embodiments. The vertical cross-sectional view in FIG. 1A is along the line A-A′ in FIG. 1B. The package structure 100 may include a first set of semiconductor dies (e.g., primary dies such as a system on chip (SOC) die) and a second set of semiconductor dies (e.g., secondary dies such as memory/SOC dies, high bandwidth memory (HBM) dies, etc.). The first set of semiconductor dies may include, for example, first semiconductor die 141. The second set of semiconductor dies may include, for example, a second semiconductor die 142, and third semiconductor die 143 (see FIG. 1B). The first semiconductor die 141, second semiconductor die 142 and third semiconductor die 143 may be referred to collectively as the semiconductor dies 140 (see FIG. 1B).

Although the package structure 100 is illustrated as including a particular number of semiconductor dies 140 having a particular arrangement, the number of semiconductor dies 140 and the arrangement of the semiconductor dies 140 is not limited to any particular number and arrangement. In particular, the package structure 100 may include any number and arrangement of semiconductor dies 140 and any number and arrangement of semiconductor die sets.

Referring to FIGS. 1A and 1B, the package structure 100 may include a package substrate 110 and a semiconductor die module 120, wherein the semiconductor die module 120 may include the semiconductor dies 140. The semiconductor die module 120 may be mounted on the package substrate 110. The package structure 100 may further include a ring structure 130 on the package substrate 110 adjacent to the semiconductor die module 120. The ring structure may include an outer ring 130a and an inner ring 130b mounted between the outer ring 130a and the semiconductor die module 120. The ring structure 130 may be attached to the package substrate 110 by an adhesive 160. The package structure 100 may include, for example, a chip-on-wafer-on-substrate (CoWoS®) design, an integrated fan-out (such as InFO-oS) design, etc.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 114a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) (e.g., or land-grid array (LGA)) including a plurality of solder balls 110c may be formed on the board-side surface of the package substrate lower dielectric layer 116. The solder balls 110c may allow the package structure 100 to be securely mounted (e.g., by surface mount technology (SMT)) on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b.

The solder balls 110c of the BGA may include a solder material including one or more of tin, copper, silver, bismuth, indium, zinc, and antimony. In particular, the solder material may include a tin-silver-copper alloy including about 3-4% silver, 0.5-0.7% copper, and the balance (95% or more) tin. A fourth metal such as zinc or manganese may be added to the tin-silver-copper alloy. The solder material may have a melting point in a range from 90° C. to 450° C., and more particularly, in a range from about 220° C. to 260° C.

The semiconductor die module 120 may be mounted by C4 bumps 121 on the package substrate upper bonding pads 114a in the package substrate 110. A package underfill layer 129 may be formed under and around the semiconductor die module 120 and the C4 bumps 121 so as to fix the semiconductor die module 120 to the package substrate 110. The package underfill layer 129 may be formed of an epoxy-based polymeric material.

The semiconductor die module 120 may include an interposer 10 having a redistribution layer (RDL) structure. The interposer 10 may be electrically coupled to the package substrate 110 by the C4 bumps 121. The semiconductor dies 140 (see FIG. 1B) may be mounted on the interposer 10.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of polymer layers 12 and a plurality of redistribution layers 12a stacked alternately. The number of the polymer layers 12 and/or the number of redistribution layers 12a in the interposer 10 are not limited by the disclosure. While the interposer 10 is shown to have three (3) polymer layers 12, a greater or fewer number of layers may be used.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof or other suitable metals.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12 and may extend in the x-direction (e.g., first horizontal direction) and y-direction (e.g., second horizontal direction) on an upper surface of the polymer layers 12.

An upper passivation layer 13 may be formed on the chip-side surface of the interposer 10. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

One or more interposer upper bonding pads 13a may be located in the upper passivation layer 13 on the chip-side surface of interposer 10. The upper passivation layer 13 may at least partially cover the interposer upper bonding pads 13a. That is, the interposer upper bonding pads 13a may be at least partially exposed on the chip-side surface of the interposer 10. The interposer upper bonding pads 13a may be connected to the redistribution layers 12a. The interposer upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 14 may be formed on the board-side surface of the interposer 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material.

One or more interposer lower bonding pads 14a may be located on the board-side surface of interposer 10. The interposer lower bonding pads 14a may be bonded to and electrically connected to the redistribution layers 12a. The interposer lower bonding pads 14a may be located in the lower passivation layer 14. The lower passivation layer 14 may at least partially cover the interposer lower bonding pads 14a. That is, the interposer lower bonding pads 14a may be at least partially exposed on the board-side surface of the interposer 10. The interposer lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

One or more integrated passive devices (IPDs) (not shown) may optionally be located on the board-side surface of interposer 10. The IPDs may be bonded to and electrically connected to the redistribution layers 12a. The IPDs may be located in the lower passivation layer 14. The IPDs may include an exposed portion that projects out from the lower passivation layer. The IPDs may include one or more electronic components such as resistors, capacitors, inductors, coils, chokes, microstriplines, impedance matching elements, baluns, etc. The IPDs may be electrically coupled to the semiconductor dies 140 through the interposer 10.

The semiconductor dies 140 may be mounted on the interposer 10 by microbumps 128 that may be bonded to the interposer upper bonding pads 13a. The semiconductor dies 140 may therefore be electrically coupled to the metal interconnects 12a by the microbumps 128.

An interposer underfill layer 126 may be formed around the microbumps 128 and between the semiconductor dies 140 and the interposer 10. The interposer underfill layer 126 may be formed separately under each of the semiconductor dies 140. Alternatively, the interposer underfill layer 126 may be formed continuously as one layer under all of the semiconductor dies 140 as illustrated in FIG. 1A. The interposer underfill layer 126 may also be formed between each of the semiconductor dies 140. The interposer underfill layer 126 may also be formed of an epoxy-based polymeric material.

Each of the semiconductor dies 140 may include, for example, a singular semiconductor die, a system on chip (SOC) die, or a system on integrated chips (SoIC) die, and may be implemented by chip on wafer on substrate (CoWoS®) technology or integrated fan-out on substrate (INFO-oS) technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, a static random access memory (SRAM) die, etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure.

The semiconductor die module 120 may also include an upper molding material layer 127 formed around the semiconductor dies 140. The upper molding material layer 127 may also be formed on and around the interposer underfill layer 126.

In at least one embodiment, a height of an upper surface of the interposer underfill layer 126 may be less than a height of an upper surface of the semiconductor dies 140, and the upper molding material layer 127 may be formed on sidewalls (inner sidewall and outer sidewall) of each of the semiconductor dies 140. In particular, the upper molding material layer 127 may be formed between and bonded to the sidewalls of each of the semiconductor dies 140. The upper molding material layer 127 may have an outer sidewall that is substantially aligned with the outer sidewall of the interposer 10. The molding material layer 127 may be formed, for example, of an epoxy molding compound (EMC).

The package structure 100 may also include a ring structure 130 that may be fixed to the package substrate 110 adjacent to the semiconductor die module 120. The ring structure may provide rigidity to the package substrate 110. The ring structure 130 may be formed, for example, of metal, ceramic or polymer material. In at least one embodiment, the ring structure 130 may be formed of a metal or metal alloy including various metals such as copper, iron, aluminum, nickel, chromium, etc. In at least one embodiment, the ring structure 130 may include copper (e.g., with a nickel coating), an iron-nickel alloy (e.g., Alloy 42), a stainless steel (e.g., SUS430), a welded metal, etc. Other suitable metal materials for use in the ring structure 130 are within the contemplated scope of disclosure.

The ring structure 130 may include an outer ring 130a and inner ring 130b located between the outer ring 130a and the semiconductor die module 120. The inner ring 130b may be separated from the outer ring 130a so that a space is formed therebetween. The inner ring 130b may function, for example, as a heat sink and help to dissipate heat in the package structure 100 (e.g., dissipate heat out of the package substrate 110). In at least one embodiment, the inner ring 130b may be joined to the outer ring 130a, so that no space is formed therebetween. The outer ring 130a may have a thickness substantially the same as a thickness of the inner ring 130b. In at least one embodiment, a thickness of the inner ring 130b may be less than a thickness of the outer ring 130a.

The outer ring 130a and inner ring 130b may include substantially similar materials. In at least one embodiment, the outer ring 130a and inner ring 130b may include different materials or different ratios of substantially similar materials, such that a coefficient of thermal expansion (CTE) of the outer ring 130a is different than a CTE of the inner ring 130b. In at least one embodiment, the outer ring 130a may include a first CTE and the inner ring 130b may include a second CTE that is greater than the first CTE. In at least one embodiment, the first CTE may be in a range from 3 ppm/° C. to 20 ppm/° C., and a CTE ratio of the second CTE to the first CTE may be in a range from 0.2 to 5.0.

In at least one embodiment, the first CTE of the outer ring 130a may be greater than a CTE of the package substrate 110 and the second CTE of the inner ring 130b may be less than the CTE of the package substrate 110. For example, in at least one embodiment the package substrate 110 may have a CTE of about 14, the outer ring 130a may include copper having a CTE of about 17.3 ppm/° C. and the inner ring 130b may include an iron-nickel alloy (e.g., Alloy42) having a CTE of about 4.3. In at least one embodiment the package substrate 110 may have a CTE of about 14, the outer ring 130a may include copper having a CTE of about 17.3 ppm/° C. and the inner ring 130b may include stainless steel (e.g., SUS430) having a CTE of about 11.

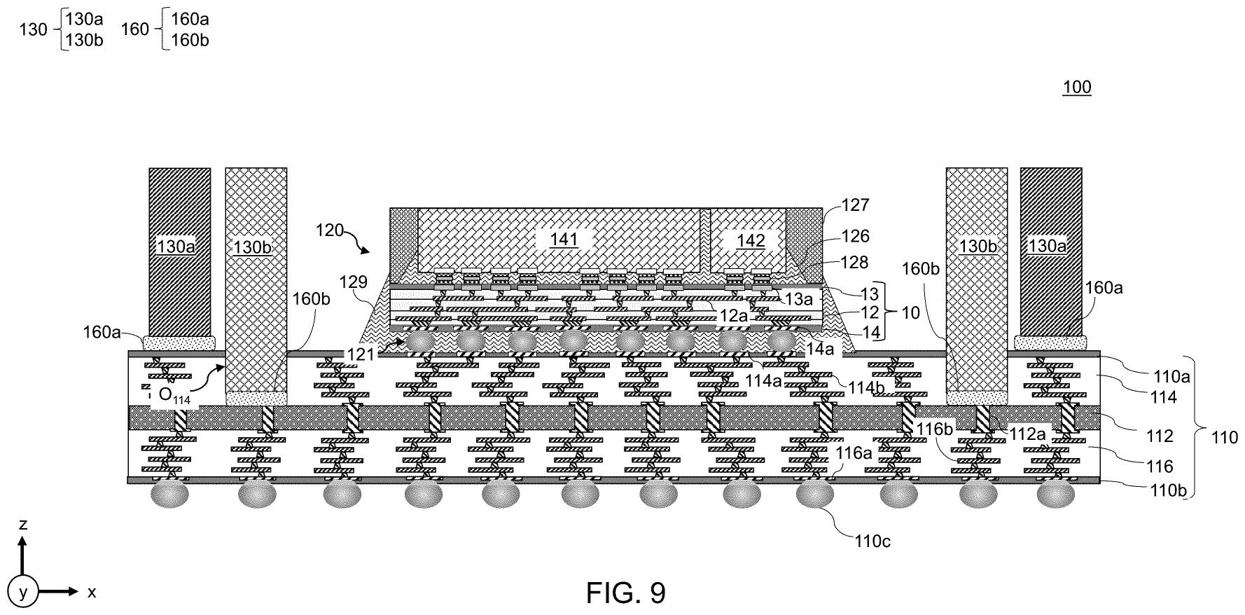

As illustrated in FIG. 1A, the outer ring 130a and inner ring 130b may be fixed to an upper surface of the package substrate 110. In at least one embodiment, the outer ring 130a and inner ring 130b may be fixed to different surfaces of the package substrate 110. See e.g., FIG. 9. In at least one embodiment, the outer ring 130a may be fixed to the upper surface of the package substrate 110 and inner ring 130b may be fixed to a surface beneath the upper surface of the package substrate 110. In particular, a trench (e.g., a ring trench) may be formed through the package substrate upper passivation layer 110a and into the package substrate upper dielectric layer 114, and the inner ring 130b may be formed in the trench. The trench may expose, for example, an upper surface of the core 112 and the inner ring 130b may be fixed to the upper surface of the core 112.

The ring structure 130 may be fixed to the package substrate 110 by an adhesive 160. In particular, the outer ring 130a may be fixed to the package substrate 110 by a first adhesive 160a and the inner ring 130b may be fixed to the package substrate 110 by a second adhesive 160b. The first adhesive 160a may adhere a bottom surface of the outer ring 130a to the package substrate 110, and the second adhesive 160b may adhere a bottom surface of the inner ring 130b to the package substrate 110.

A material of the first adhesive 160a may be substantially the same as a material of the second adhesive 160b. In at least one embodiment, the first adhesive 160a and the second adhesive 160b may have a Young's modulus value in a range from 0.1 GPa to 10 GPa. In at least one embodiment the material of the first adhesive 160a may be different than the material of the second adhesive 160b. Each of the first adhesive 160a and the second adhesive 160b may include, for example, an epoxy-based adhesive or a silicone-based adhesive. Other adhesives are within the contemplated scope of this disclosure.

In at least one embodiment, the first adhesive 160a may include a high Young's modulus adhesive such as an epoxy-based adhesive. The first adhesive 160a may have a Young's modulus greater than about 1 GPa (e.g., from 1 GPa to 10 GPa) at 25° C. The high Young's modulus adhesive comprising the first adhesive 160a may include one or more different phenolic resins.

In at least one embodiment, the second adhesive 160b may have physical properties that are different than the physical properties of the first adhesive 160a. In particular, the second adhesive 160b may have a Young's modulus that is different than the Young's modulus of the first adhesive 160a. In at least one embodiment, the second adhesive 160b may have a thermal conductivity that is greater than a thermal conductivity of the first adhesive 160a which may help to assist in heat dissipation by the inner ring 130b. In at least one embodiment, the second adhesive 160b may have a Young's modulus that is less than the Young's modulus of the first adhesive 160a. The second adhesive 160b may have a Young's modulus less than about 1 GPa (e.g., from 0.1 GPa to 1 GPa) at 25° C. The low Young's modulus adhesive comprising the second adhesive 160b may include one or more different polysiloxane resins. In at least one embodiment, the low Young's modulus adhesive may include dimethyl siloxane.

The adhesive 160 may reduce in-plane stress by including the second adhesive 160b (e.g., a low Young's modulus adhesive), and control warpage (e.g., out of plane stress) by including the first adhesive 160a (e.g., a high Young's modulus adhesive). The package structure 100 may thereby reduce stress without negatively impacting performance of package warpage control.

As illustrated in FIG. 1B, semiconductor die module 120 may be located in a central portion of the package substrate 110. The ring structure 130 may be formed on the package substrate 110 so as to laterally surround the semiconductor die module 120 in a first horizontal direction (e.g., the x-direction) and a second horizontal direction (e.g., y-direction). In the plan view of FIG. 1B, the outer ring 130a may be separated from an outer edge of the package substrate 110 by an outer package substrate portion 1100. This may allow, for example, for the first adhesive 160a to spread during assembly of the package structure 100 (e.g., during attaching of the outer ring 130a to the package substrate 110). A width of the outer package substrate portion 1100 may be substantially uniform around the entire periphery of the outer ring 130a. In at least one embodiment, the width of the outer package substrate portion 1100 may be vary around the periphery of the outer ring 130a.

The outer ring 130a may be separated from an inner ring 130b by a middle package substrate portion 110m. A width of the middle package substrate portion 110m may be substantially uniform around the entire periphery of the inner ring 130b. In at least one embodiment, the width of the middle package substrate portion 110m may be vary around the periphery of the inner ring 130b. In at least one embodiment, the outer ring 130a may contact the inner ring 130b and the middle package substrate portion 110m may be not present. In at least one embodiment, the outer ring 130a may contact the inner ring 130b in one direction (e.g., the x-direction) and be separated from the inner ring 130a in the other direction (e.g., the y-direction). In that case, the middle package substrate portion 110m may be not present in the one direction but present in the other direction.

The inner ring 130b may be separated from the semiconductor die module 120 (e.g., from the package underfill layer 129) by an inner package substrate portion 110i. A width of the inner package substrate portion 110i may be substantially uniform around the entire periphery of the semiconductor die module 120. In at least one embodiment, a width of the inner package substrate portion 110i may vary around the entire periphery of the semiconductor die module 120.

In the plan view, an outer shape of each of the semiconductor die module 120 and the package substrate 110 may include a rectangular shape or a square shape. Other shapes are within the contemplated scope of disclosure. The semiconductor die module 120 and package substrate 110 may have a symmetrical arrangement in which an outer shape of the semiconductor die module 120 may be substantially the same as an outer shape of the package substrate 110. In at least one embodiment, the semiconductor die module 120 and package substrate 110 may have an asymmetrical arrangement in which the outer shape of the semiconductor die module 120 may be different than the outer shape of the package substrate 110.

In at least one embodiment, each of the semiconductor die module 120 and the package substrate 110 may include a rectangular shape. In that case, a longitudinal direction of the semiconductor die module 120 may be substantially the same as a longitudinal direction of the package substrate 110. In at least one embodiment, the longitudinal direction of the semiconductor die module 120 may be perpendicular to the longitudinal direction of the package substrate 110.

The semiconductor dies 140 may be arranged in the semiconductor die module 120 so that the first semiconductor die 141 is located on a first side of the semiconductor die module 120 in a longitudinal direction of the semiconductor die module 120 (e.g., the x-direction). The second semiconductor die 142 and third semiconductor die 143 may be located on a second side of the semiconductor die module 120 in the longitudinal direction of the semiconductor die module 120. The second semiconductor die 142 and third semiconductor die 143 may be substantially aligned in a direction perpendicular to the longitudinal direction of the semiconductor die module 120 (e.g., the y-direction).

As further illustrated in FIG. 1B, a shape of the outer ring 130a and a shape of the inner ring 130b in the plan view may be substantially the same as a shape of the package substrate 110. In at least one embodiment, the shape of the outer ring 130a and/or the shape of the inner ring 130b may be different than the shape of the package substrate 110.

A shape of the outer ring 130a may be substantially the same as a shape of the inner ring 130b. In at least one embodiment, the shape of the outer ring 130a may be different than the shape of the inner ring 130b. Each of the outer ring 130a and the inner ring 130b may have a square shape or rectangle shape in the plan view. Other suitable shapes of the outer ring 130a and inner ring 130b may be within the contemplated scope of disclosure. For example, each of the outer ring 130a and the inner ring 130b may have a circular shape, oval shape, hexagonal shape, octagonal shape, polygonal shape, etc.

FIG. 1C is a detailed vertical cross-sectional view of the ring structure 130 and adhesive 160 according to one or more embodiments. As illustrated in FIG. 1C, a space S1 may be formed between an outer sidewall of the outer ring 130a and the edge of the package substrate 110. A space S2 may be formed between an inner sidewall of the outer ring 130a and an outer sidewall of the inner ring 130b. A space S3 may be formed between an inner sidewall of the inner ring 130b and a sidewall of the semiconductor die module 120.

The inner sidewall of the inner ring 130b may be separated from the semiconductor die module 120 (e.g., from the molding material layer 127) by an inner distance Dᵢ. In at least one embodiment, the inner distance Dᵢ may be in a range from 1 mm to 5 mm. In at least one embodiment, the inner distance Dᵢ may be about 3 mm. The inner distance Dᵢ may be substantially uniform or may vary around the periphery of the semiconductor die module 120.

The inner sidewall of the outer ring 130a and the outer sidewall of the inner ring 130b may be separated by a middle distance Dₘ. In at least one embodiment, the middle distance Dₘ may be less than 3 mm. In at least one embodiment, there may be no space S2 (e.g., Dₘ=0) and the inner sidewall of the outer ring 130a may contact the outer sidewall of the inner ring 130b. The middle distance Dₘ may be substantially uniform of may vary around the periphery of the inner ring 130b.

The outer ring 130a may be separated from the edge of the package substrate 110 by an outer distance Dₒ to allow for spreading of the adhesive 160. The outer distance Dₒ may be less than the inner distance Dᵢ. In at least one embodiment, the outer distance Dₒ may be in a range from 5% to 50% of the inner distance Dᵢ. The outer distance Dₒ may be less than the middle distance Dₘ. In at least one embodiment, the outer distance Dₒ may be in a range from 10% to 30% of the middle distance Dₘ. In at least one embodiment, the outer distance Dₒ may be in a range from 0.1 mm to 1.0 mm. In at least one embodiment, the outer distance Dₒ may be about 0.2 mm. The outer distance Dₒ may be substantially uniform of may vary around the periphery of the outer ring 130a.

The outer ring 130a may have a first thickness H1 (in the z-direction) in a range from 0.1 mm to 10 mm. The outer ring 130a may have a first width W1 (in the x-direction) in a range from 0.5 mm to 10 mm. In at least one embodiment, the first width W1 may be in a range from 10% to 50% of the first thickness H1.

The inner ring 130b may have a second thickness H2 (in the z-direction) that may be substantially equal to or less than the first thickness H1. In at least one embodiment, a ratio of the second thickness H2 of the inner ring 130b to the first thickness H1 of the outer ring 130a may be in a range from 0.5 to 1.0. The inner ring 130b may have a second width W2 (in the x-direction) that may be substantially the same as the first width W1 of the outer ring 130a. In at least one embodiment, a ratio of the second width W2 of the inner ring 130b to the first width W1 of the outer ring 130a may be in a range from 0.8 to 1.2. In at least one embodiment, the second width W2 of the inner ring 130b may be greater than the first width W1 of the outer ring 130a, and the second thickness H2 of the inner ring 130b may be less than the first thickness H1 of the outer ring 130a.

The overall thickness of the adhesive 160 may be less than the overall thickness of the ring structure 130 (e.g., less than the first thickness H1). A thickness of the first adhesive 160a may be substantially the same as the thickness of the second adhesive 160b. In particular, the thickness of the first adhesive 160a and the thickness of the second adhesive 160b may each be in a range from 50 μm to 150 μm (e.g., about 100 μm). In at least one embodiment, the thickness of the second adhesive 160b may be greater than the thickness of the first adhesive 160a. In particular, the thickness of the first adhesive 160a may be in a range from 50 μm to 150 μm (e.g., about 100 μm) and the thickness of the second adhesive 160b may be in a range from 300 μm to 400 μm (e.g., about 350 μm).

An overall width (in the x-direction) of the adhesive 160 may be substantially the same as an overall width of the ring structure 130. A width W160a of the first adhesive 160a may be substantially the same as a width W1 of the outer ring 130a. A width W160b of the second adhesive 160b may be substantially the same as a width W2 of the inner ring 130b.

As further illustrated in FIG. 1C, an upper surface of the outer ring 130a may be substantially uniform over a width (in the x-direction) of the outer ring 130a. An upper surface of the inner ring 130b may be substantially uniform over a width (in the x-direction) of the inner ring 130b. A height of the upper surface of the outer ring 130a and a height of the upper surface of the inner ring 130b may each be substantially uniform around the entire periphery of the semiconductor die module 120. The upper surface of the outer ring 130a may be substantially coplanar with the upper surface of the inner ring 130b around the entire periphery of the semiconductor die module 120.

The upper surface of the outer ring 130a and the upper surface of the inner ring 130b may each have a height (in the z-direction) as measured from an upper surface of the package substrate 110 that is greater than a height H120 of an upper surface of the semiconductor die module 120. In particular, a height difference HD between the height H120 of the upper surface of the semiconductor die module 120 and the height H130b of the upper surface of the inner ring 130b may be 0.1 mm or greater. In at least one embodiment (e.g., where H1 is in a range from 0.1 mm to 10 mm and the ratio of H2 to H2 is in a range from 0.5 to 1), a ratio of the height H130b of the upper surface of the inner ring 130b to the height H120 of the upper surface of the semiconductor die module 120 may be in a range from 1 to 3.

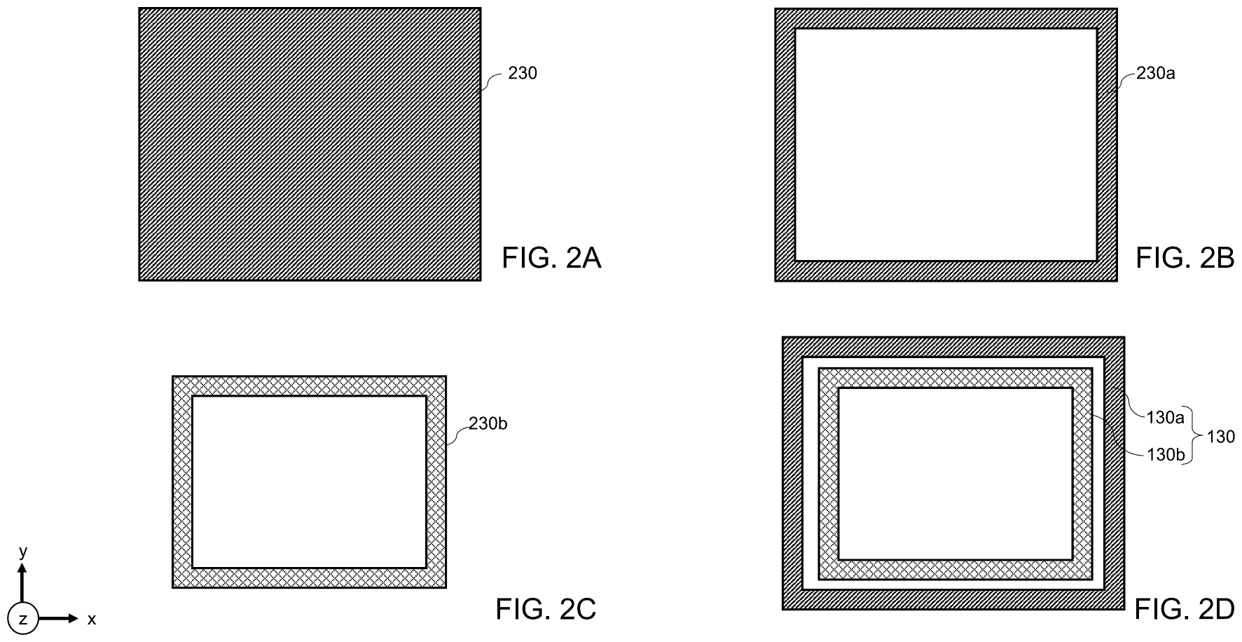

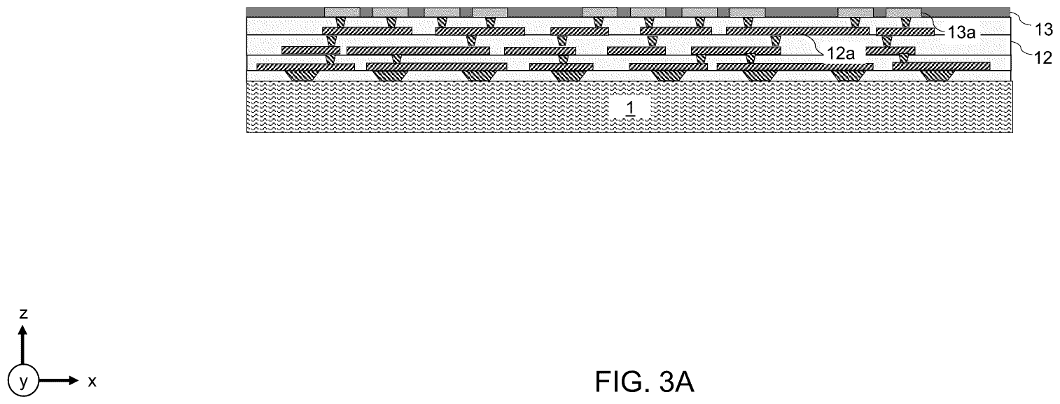

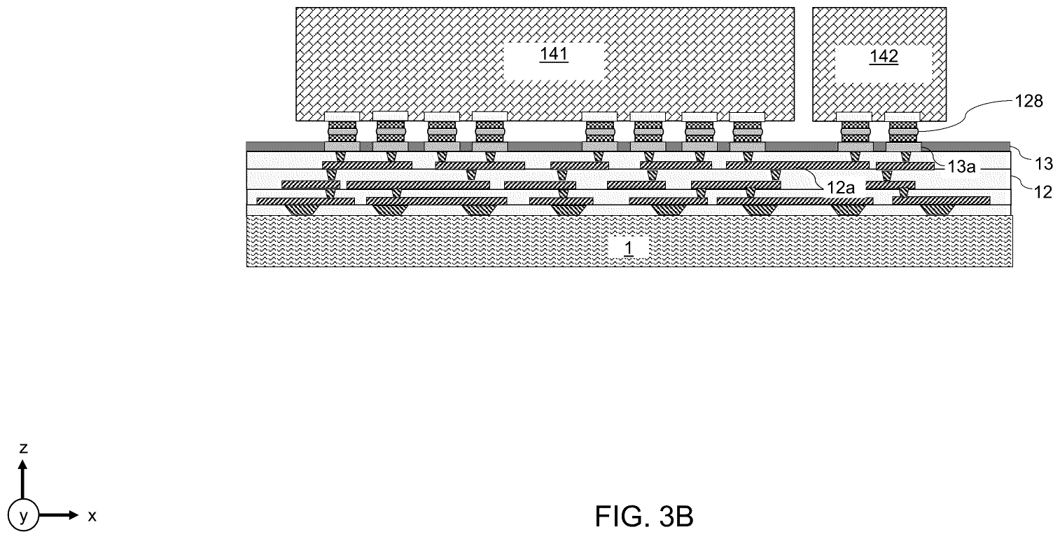

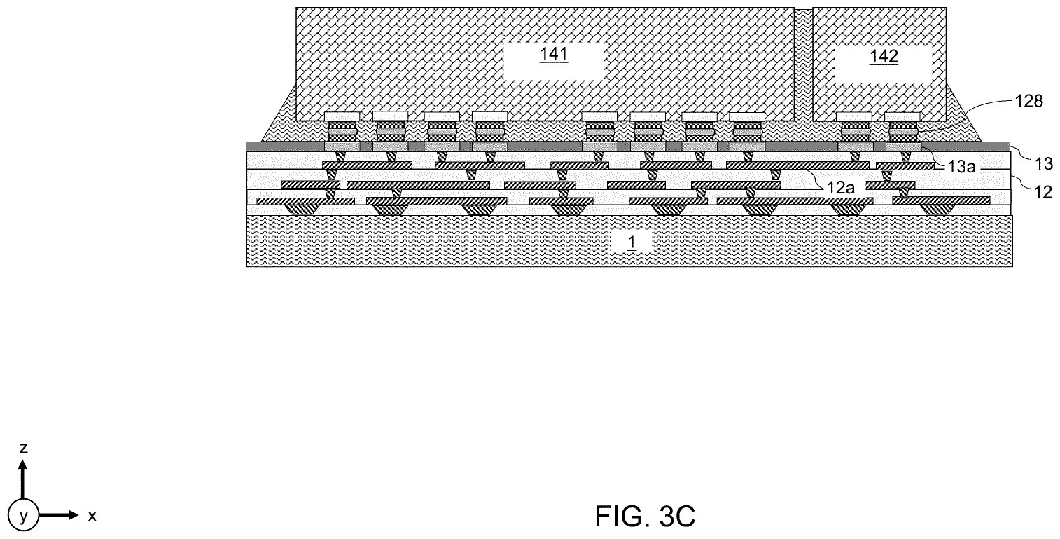

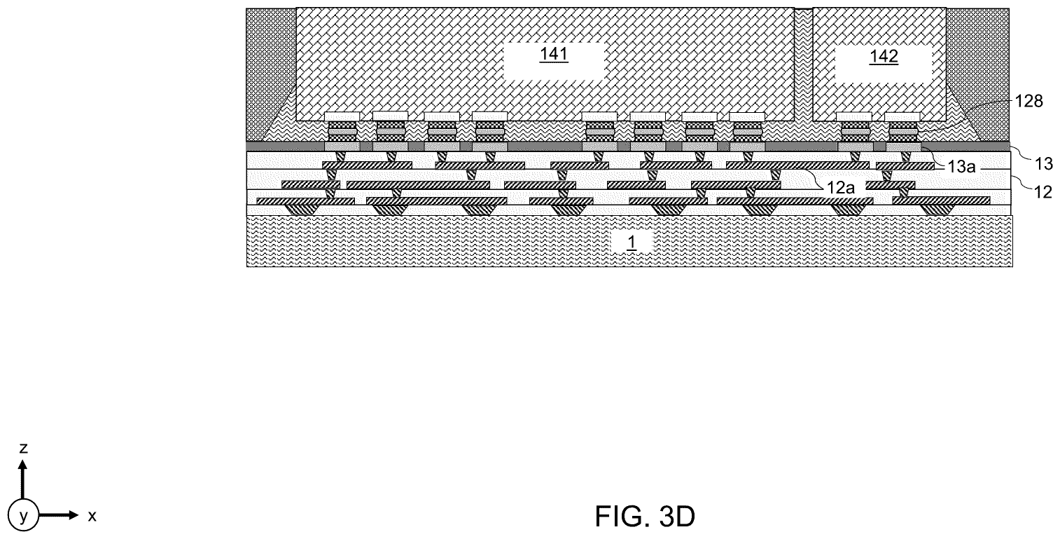

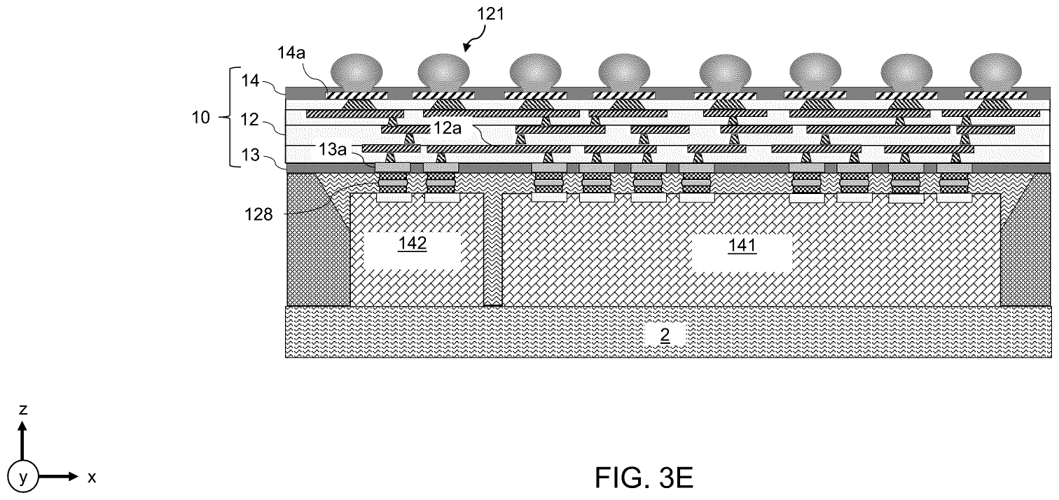

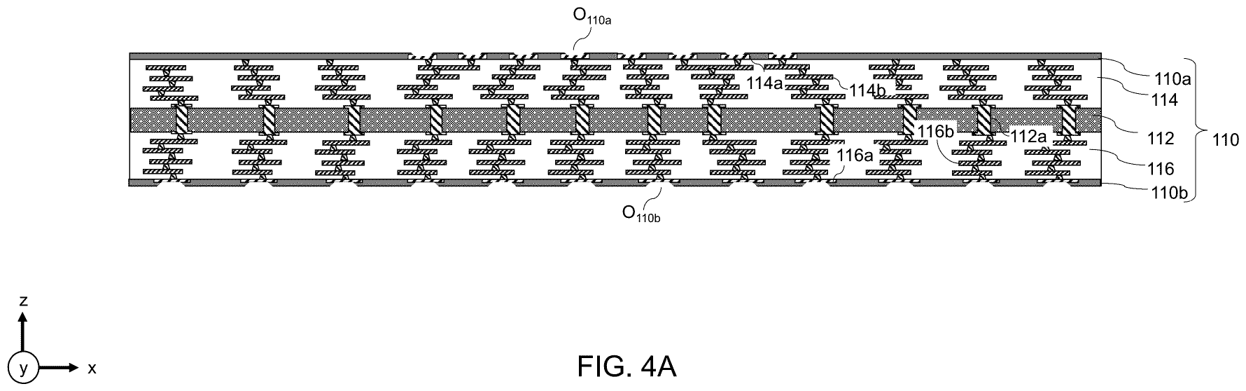

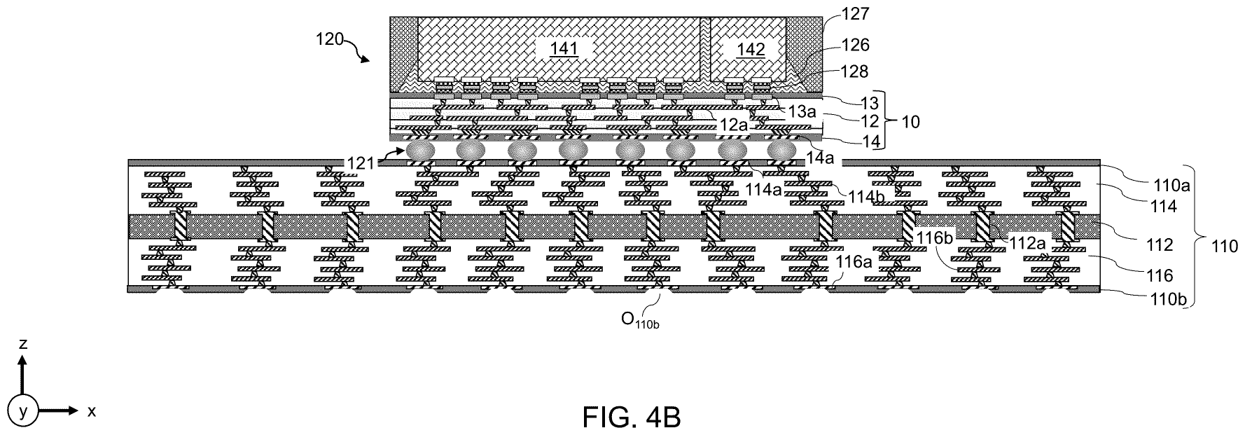

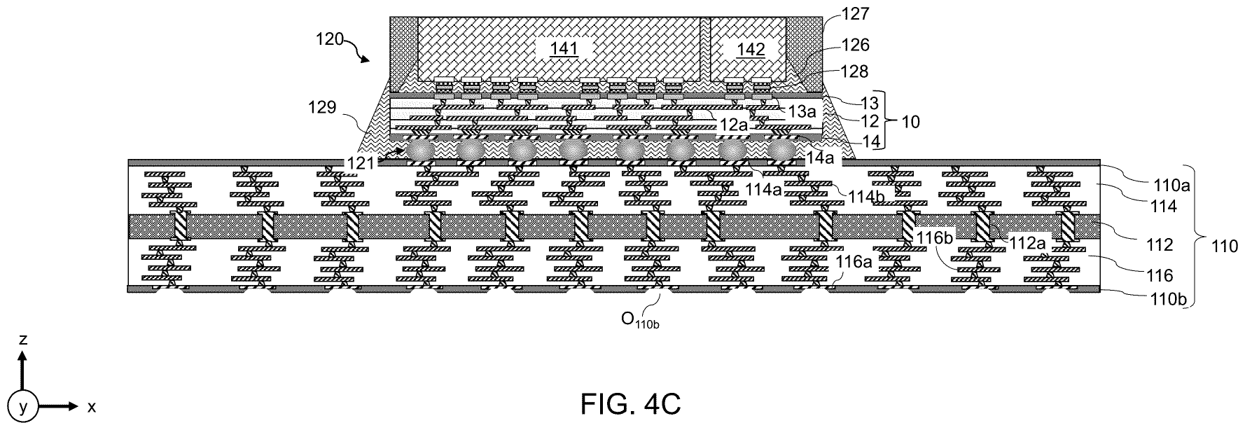

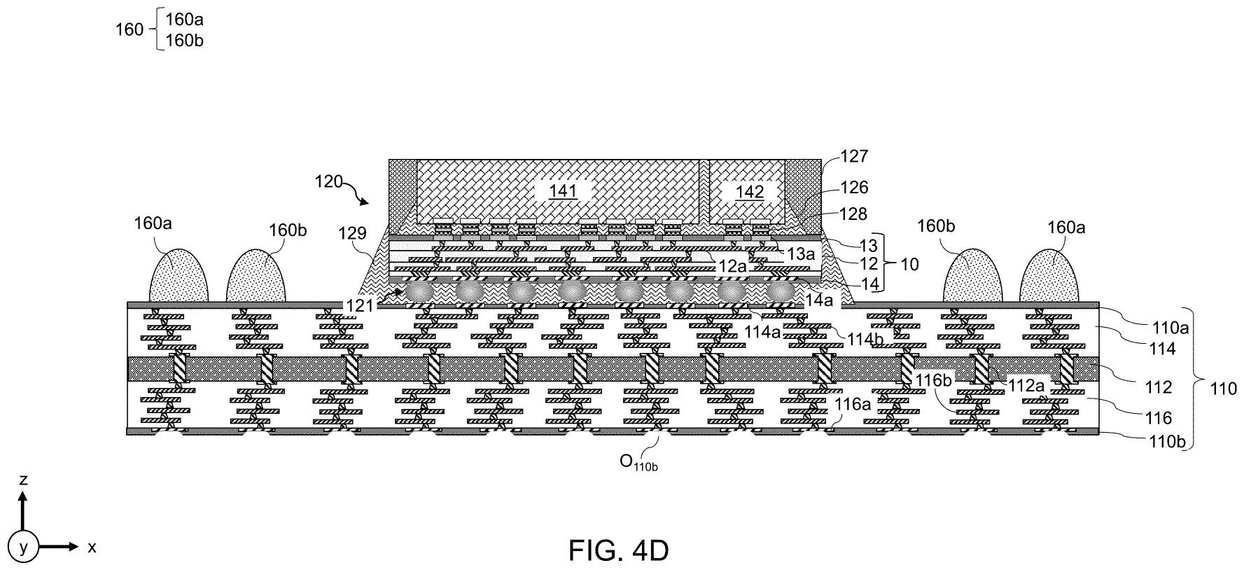

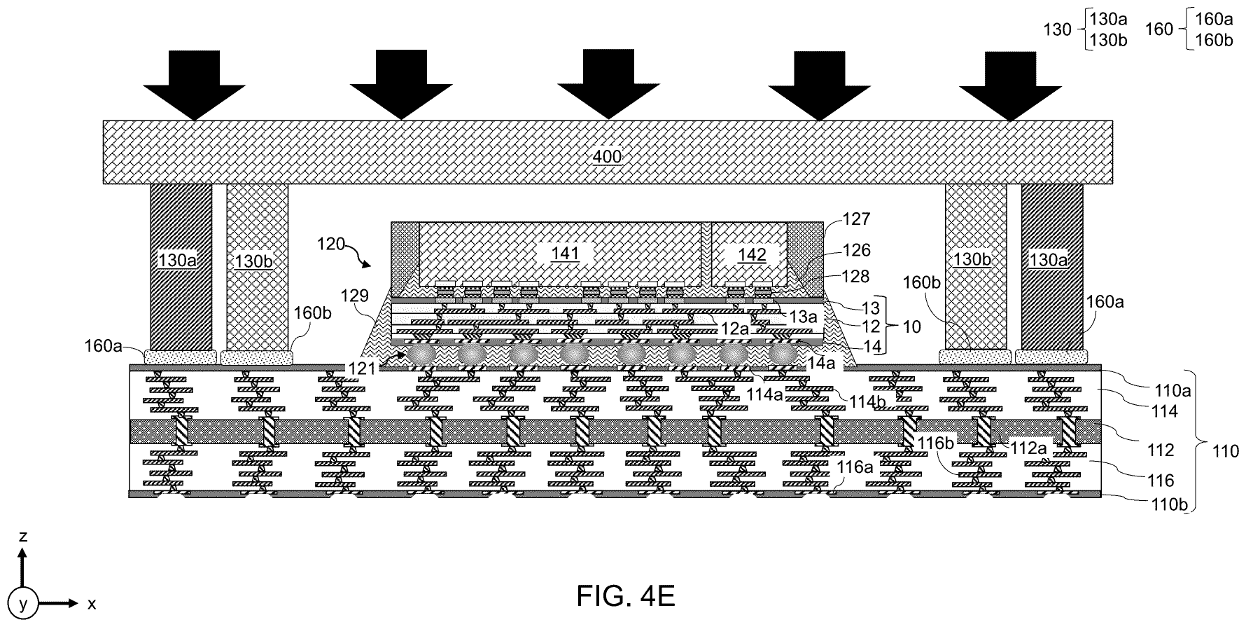

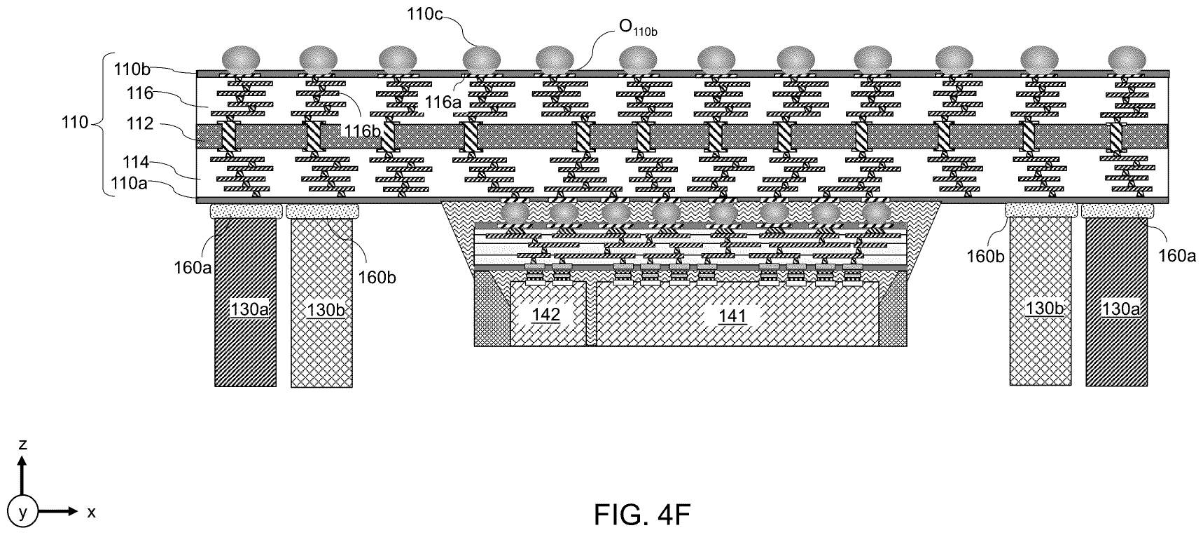

FIGS. 2A-4G illustrate various intermediate structures in a method making the package structure 100. In particular, FIGS. 2A-2D illustrate various intermediate structures in a method making the ring structure 130 of the package structure 100. FIGS. 3A-3E illustrate various intermediate structures in a method making the semiconductor die module 120 of the package structure 100. FIGS. 4A-4G illustrate various intermediate structures in a method making the package structure 100.

FIG. 2A is a plan view (e.g., top-down view) of an intermediate structure including a metal sheet 230, according to one or more embodiments. The metal sheet 230 may include, for example, a metal material such as copper, copper alloy, iron-nickel alloy, stainless steel, etc. Other metal materials are within the contemplated scope of this disclosure. An outer shape of the metal sheet 230 may include a rectangular shape. Other shapes are within the contemplated scope of disclosure. The outer shape of the metal sheet 230 may be substantially the same as the outer shape of the outer ring 130a (see FIG. 1B). The dimensions of the metal sheet 230 in the x-direction and in the y-direction may be substantially the same as the dimensions of the outer ring 130a (see FIG. 1B) in the x-direction and in the y-direction, respectively.

A thickness (in the z-direction) of the metal sheet 230 may be substantially uniform over the entire area of the metal sheet 230. The thickness of the metal sheet 230 may be substantially the same as the thickness H1 of the outer ring 130a (see FIG. 1C). In at least one embodiment, the thickness of the metal sheet 230 may be in a range from 0.1 mm to 10 mm.

FIG. 2B is a plan view (e.g., top-down view) of an intermediate structure including a metal sheet 230a having a frame shape, according to one or more embodiments. The metal sheet 230 in FIG. 2A may be stamp pressed to form the frame-shaped metal sheet 230a in FIG. 2B. In particular, the metal sheet 230 in FIG. 2A may be stamp pressed using a stamping press to form the frame-shaped metal sheet 230a. In particular, the stamping press may include at least a 60-ton stamping press.

FIG. 2C is a plan view (e.g., top-down view) of an intermediate structure including a metal sheet 230b having a frame shape, according to one or more embodiments. The metal sheet 230b having a frame shape may be formed by a process that is substantially the same as the process of forming the metal sheet 230a described above. The shape and dimensions of the metal sheet 230a and the metal sheet 230b, may be substantially the same as the shape and dimensions of the outer ring 130a and inner ring 130b, respectively.

FIG. 2D is a plan view (e.g., top-down view) of an intermediate structure including the ring structure 130 having the outer ring 130a and the inner ring 130b, according to one or more embodiments. The ring structure 130 in FIG. 2D may be formed by performing a plating process on the metal sheet 230a in FIG. 2B and the metal sheet 230b in FIG. 2C. The plating process may apply a metal plating layer to a surface (e.g., entire surface) of the metal sheet 230a and the metal sheet 230b. A material of the metal plating layer may include, for example, nickel. Other materials are within the contemplated scope of disclosure. The metal plating layer may increase the strength of the ring structure 130 and enhance the corrosion resistance of the ring structure 130. The plating process may include, for example, an electroless metal plating process.

FIG. 3A is a vertical cross-sectional view of an intermediate structure including a portion of the interposer 10 (e.g., organic interposer) formed on a first carrier substrate 1 (e.g., carrier wafer) according to an embodiment of the present invention. The lower passivation layer 14 and interposer lower bonding pads 14a of the interposer 10 may be formed later in the method of forming the semiconductor die module 120.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used.

An adhesive layer (not shown) may be applied to the top surface of the first carrier substrate 1. In at least one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

A plurality of dielectric layers 12 and plurality of redistribution layers 12a may be alternately formed on the first carrier substrate 1 (e.g., on the adhesive layer on the first carrier substrate 1). It should be noted that although FIG. 3A illustrates four dielectric layers 12 and three redistribution layers 12a, more or fewer dielectric layers 12 and redistribution layers 12a are contemplated by the present disclosure.

Each dielectric layer 12 may each be formed, for example, by depositing (e.g., by CVD, PVD or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 3A, the interposer upper bonding pads 13a may then be formed on the uppermost dielectric layer 12. The interposer upper bonding pads 13a may include any metallic material that may be bonded to a solder material. The interposer upper bonding pads 13a may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process to form the interposer upper bonding pads 13a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the interposer upper bonding pads 13a may include an underbump metallurgy (UBM) layer stack deposited over the adhesive layer. The order of material layers within the UBM layer stack may be selected such that solder material portions may be subsequently bonded to portions of the bottom surface of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the interposer upper bonding pads 13a. In at least one embodiment, the interposer upper bonding pads 13a may be arranged as a two-dimensional array, which may be a two-dimensional periodic array such as a rectangular periodic array.

The upper passivation layer 13 may then be formed on the chip-side surface of the interposer 10 and over the interposer upper bonding pads 13a. The upper passivation layer 13 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, chemical mechanical polishing (CMP), etc.) so as to form the upper passivation layer 13.

FIG. 3B is a vertical cross-sectional view of an intermediate structure including the first semiconductor die 141 and second semiconductor die 142, according to one or more embodiments. The semiconductor dies 140 may be placed on the interposer 10, for example, by using an electro-mechanical pick-and-place (PNP) machine. Each of the semiconductor dies 140 may then be bonded to the interposer 10 by one or more microbumps 128. In at least one embodiment, the microbumps 128 may include a two-dimensional array of microbumps 128. Each of the semiconductor dies 140 may be attached to the interposer upper bonding pads 13a by a C2 bonding process, (e.g., solder bonding). In the C2 bonding process, an upper microbump portion (including a solder portion) may be positioned over a lower microbump portion formed on the interposer upper bonding pads 13a in the upper surface of the interposer 10. The intermediate structure may then be heated to cause reflow of the solder portion of the upper microbump portion.

Other methods of bonding the semiconductor dies 140 to the interposer 10 are within the contemplated scope of disclosure. In at least one embodiment, each of the semiconductor dies 140 may be bonded to the interposer 10 by a hybrid bond (i.e., a direct bond that may include a dielectric-to-dielectric bond, a polymer-to-polymer bond, and/or a metal-to-metal bond). In that embodiment, bonding pads within the semiconductor dies 140 may be positioned on the interposer upper bonding pads 13a. In addition, an oxide layer and/or polymer layer of the semiconductor dies 140 may be positioned on the upper passivation layer 13. The intermediate structure may then be heated to bond the bonding pads of the semiconductor dies 140 to the interposer upper bonding pads 13a and bond the oxide layer and/or polymer layer of the semiconductor dies 140 to the upper passivation layer 13.

FIG. 3C is a vertical cross-sectional view of an intermediate structure including the interposer underfill layer 126 according to one or more embodiments. The interposer underfill layer 126 may be applied by depositing and/or injecting an epoxy-based polymeric material onto the interposer 10. The epoxy-based polymeric material may be applied on the interposer 10 so as to be formed under the semiconductor dies 140 and around the microbumps 128. In at least one embodiment, the epoxy-based polymeric material may fill substantially all of the gaps between the semiconductor dies 140 and the interposer 10. The interposer underfill layer 126 may then be cured, for example, in a box oven for duration in a range from 60 minutes to 120 minutes at a temperature in a range from 120° C. to 180° C. to provide the interposer underfill layer 126 with a sufficient stiffness and mechanical strength.

FIG. 3D is a vertical cross-sectional view of an intermediate structure including the molding material layer 127, according to one or more embodiments. The molding material layer 127 (e.g., encapsulant layer) may be formed by a sequence of an over-molding process and a planarization process. In particular, the molding material layer 127 may include an epoxy polymer material (e.g., an epoxy molding compound (EMC). The molding material layer 127 may be formed on the interposer 10 and fill in the gaps between the semiconductor dies 140. The molding material layer 127 may encapsulate (e.g., in the x-direction and y-direction) the semiconductor dies 140. The molding material layer 127 may be formed, for example, by a deposition process such as CVD, PECVD, PVD, spin coating, lamination or other suitable deposition technique.

The molding material layer 127 may be deposited so as to completely cover the semiconductor dies 140 and the interposer underfill layer 126. After the molding material layer 127 has cured, a planarization process may then be used to make an upper surface of the molding material layer 127 substantially coplanar with an upper surface of the semiconductor dies 140. The planarization process may be performed on the upper surface of the molding material layer 127 until an upper surface of the semiconductor dies 140 are exposed. The planarization process may include, for example, a mechanical grinding process and/or a CMP process.

FIG. 3E illustrates a vertical cross-sectional view of an intermediate structure including the plurality of C4 bumps 121, according to one or more embodiments. After the upper molding material layer 127 has been cured and planarized (e.g., by grinding, CMP, etc.), a second carrier substrate 2 may be attached to the intermediate structure of FIG. 3D. In particular, the second carrier substrate 2 may be attached to the upper surface of the molding material layer 127 and the upper surface of the semiconductor dies 140. The intermediate structure of FIG. 3D may then be inverted and the first carrier substrate 1 may be detached from the lower polymer layer 12 of the interposer 10. The first carrier substrate 1 may be detached from the interposer 10, for example, by deactivating the adhesive layer (not shown) adhering the first carrier substrate 1 to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The interposer lower bonding pads 14a may then be formed on the lower polymer layer 12 of the interposer 10. The interposer lower bonding pads 14a may be formed using substantially the same materials and substantially the same photolithographic processes as described above for the interposer upper bonding pads 13a. The lower passivation layer 14 may then be formed on the lower polymer layer 12 of the interposer 10 and over the interposer lower bonding pads 14a. The lower passivation layer 14 may be formed using the same materials and processes described above for the upper passivation layer 13. The lower passivation layer 14 may then be etched by a suitable etching process (e.g., by wet etching, dry etching, etc.) to form openings over the interposer lower bonding pads 14a and expose a surface of the interposer lower bonding pads 14a.

The plurality of C4 bumps 121 may then be formed on the intermediate structure. The C4 bumps 121 may include, for example, solder bumps formed in the openings in the lower passivation layer 14 over the interposer lower bonding pads 14a, for example, by an electroplating process. The plurality of C4 bumps 121 may contact the interposer lower bonding pads 14a through the openings in the lower passivation layer 14. In at least one embodiment, the C4 bumps 121 may be formed by forming one or more underbump metallization (UBM) layers (not shown) on the interposer lower bonding pads 14a, forming contact pads on the UBM layers, and forming the solder bumps on the contact pads.

FIG. 4A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a may include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially co-planar with an upper surface of the package substrate upper bonding pads 114a and package substrate lower bonding pads 116a, respectively.

Openings O110a may then be formed in the package substrate upper passivation layer 110a so as to expose the upper surface of the package substrate upper bonding pads 114a. Openings O110b may be formed in the package substrate lower passivation layer 110b to expose an upper surface of the package substrate lower bonding pads 116a. The openings O110a and the openings O110b may be formed, for example, by using a photolithographic process. In at least one embodiment, the openings O110a and the openings O110b may be formed in separate photolithographic processes.

The photolithographic process (e.g., processes) used to form the openings O110a may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O110b may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O110a are formed in the package substrate upper passivation layer 110a and the openings O110b are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 4B illustrates a vertical cross-sectional view of an intermediate structure in which the semiconductor die module 120 may be mounted on the package substrate 110, according to one or more embodiments. The semiconductor die module 120 may be mounted on the package substrate 110, for example, by a flip chip bonding (FCB) process. The semiconductor die module 121 may be positioned over the package substrate 110, for example, by an electromechanical pick-and-place (PNP) machine. The C4 bumps 121 on the semiconductor die module 121 may then be lowered onto the package substrate upper bonding pads 114a of the package substrate 110 and heated in order to collapse the C4 bumps 121 and bond the C4 bumps 121 to the package substrate upper bonding pads 114a.

FIG. 4C illustrates a vertical cross-sectional view of an intermediate structure in which the package underfill layer 129 may be formed on the package substrate 110 according to one or more embodiments. The package underfill layer 129 may be formed of an epoxy-based polymeric material. As illustrated in FIG. 4C, the package underfill layer 129 may be formed (e.g., injected) under and around the semiconductor die module 120 and the C4 bumps 121 to the package substrate 110. The package underfill layer 129 may then be cured, for example, in a box oven for duration in a range from 60 minutes to 120 minutes at a temperature in a range from 120° C. to 180° C. to provide the interposer underfill layer 126 with a sufficient stiffness and mechanical strength.

FIG. 4D illustrates a vertical cross-sectional view of an intermediate structure in which the adhesive 160 may be applied to the package substrate 110 according to one or more embodiments. The first adhesive 160a and the second adhesive 160b may be applied separately in two separate applications. For example, the second adhesive 160b may be applied in a first step, and the first adhesive 160a may be applied in a second step after the first step. In at least one embodiment, the order of application may be reversed. In the embodiment of separate application, separate dispensing tools may be used to dispense each of the first adhesive 160a and the second adhesive 160b. Alternatively, the first adhesive 160a and the second adhesive 160b may be applied concurrently in one step. In the embodiment of concurrent application, a combination dispensing tool having dual dispensing nozzles may be used. The combination dispensing tool may include a first nozzle for dispensing the first adhesive 160a and a second nozzle adjacent the first nozzle for dispensing the second adhesive 160b. The combination dispensing tool may dispense the first adhesive 160a from the first nozzle at a first dispensing rate, and dispense the second adhesive 160b from the second nozzle at a second dispensing rate substantially the same as the first dispensing rate. In a case where a thickness of the second adhesive 160b is greater than a thickness of the first adhesive 160a, the combination dispensing tool may dispense the first adhesive 160a from the first nozzle at a first dispensing rate, and dispense the second adhesive 160b from the second nozzle at a second dispensing rate greater than the first dispensing rate.

In the embodiment of both separate and concurrent applications, the dispensing tool may include an electromechanical dispensing tool. The electromechanical dispensing tool may be programmed to dispense a measured amount of adhesive for each of the first adhesive 160a and the second adhesive 160b.

The dispensing tool may dispense the adhesive for each of the first adhesive 160a and the second adhesive 160b in a frame shape around the semiconductor die module 120. At the time of application, each of the first adhesive 160a and the second adhesive 160b may be sufficiently rigid so as to form a semi-solid bead on the surface of the package substrate 110. In at least one embodiment, a viscosity of each the first adhesive 160a and the second adhesive 160b at the time of application may be 50,000 centipoise (cp) or greater. The shape of the semi-solid bead may remain substantially unchanged between the time of application by the dispensing tool and the later time of attaching the ring structure 130.

The location of the frame shape of the first adhesive 160a and the frame shape of the second adhesive 160b may correspond to a location of the outer ring 130a and the inner ring 130b, respectively (e.g., see FIG. 1B). In at least one embodiment, the dispensing tool may dispense the first adhesive 160a and the second adhesive 160b so that a gap is formed between the first adhesive 160a and the second adhesive 160b. A center of the gap between the first adhesive 160a and the second adhesive 160b may be substantially aligned with a center of the space S2. A width (in the x-direction) of the gap may be substantially the same as the middle distance Dm. In particular, the width of the gap may less than 3 mm. A pressing of the ring structure 130 onto the adhesive 160 may deform the first adhesive 160a so as to move into the gap and deform the second adhesive 160b so as to move into the gap. In at least one embodiment, the first adhesive 160a may contact the second adhesive 160b to close the gap.

FIG. 4E illustrates a vertical cross-sectional view of an intermediate structure in which the ring structure 130 may be attached to (e.g., mounted on) the package substrate 110 according to one or more embodiments. After the ring structure 130 is formed (e.g., see FIGS. 2A-2D), the ring structure 130 may be attached to the package substrate 110 with the adhesive 160.

The outer ring 130a and inner ring 130b may be attached to the package substrate 110 separate or together. In at least one embodiment, the outer ring 130a may be attached first and the inner ring 130b may be attached second. In at least one embodiment, the inner ring 130b may be attached first and the outer ring 130a may be attached second. The inner ring 130a and outer ring 130b may be moved into a position over the adhesive 160 using an electromechanical pick-and-place (PNP) machine.

The outer ring 130a may be substantially aligned with the first adhesive 160a. The outer ring 130a may then be lowered onto the first adhesive 160a so that the bottom surface of the outer ring 130a contacts an upper surface of the first adhesive 160a. The inner ring 130b may be substantially aligned with the second adhesive 160b. The inner ring 130b may then be lowered onto the second adhesive 160b so that the bottom surface of the inner ring 130b contacts an upper surface of the second adhesive 160b.

The outer ring 130a and inner ring 130b may then be pressed by a pressing force downwardly onto the first adhesive 160a and second adhesive 160b, respectively. In at least one embodiment, the outer ring 130a and inner ring 130b may pressed by the electromechanical pick-and-place (PNP) machine onto the first adhesive 160a and second adhesive 160b, respectively. The outer ring 130a and inner ring 130b may be pressed separately in two steps or together in one step.

The pressing force may be applied, for example, by a contact structure 400 that contacts an upper surface of the outer ring 130a and an upper surface of the inner ring 130b around an entire periphery of the semiconductor die module 120 (e.g., see FIG. 1B). In at least one embodiment, the contact structure 400 may have a size (e.g., area) greater than a size (e.g., area) of the outer ring 130a. In at least one embodiment, a length (in the x-direction) and width (in the y-direction) of the contact structure 400 may be greater than the length and width of the outer ring 130a, respectively. The pressing force applied by the contact structure 400 to the outer ring 130a and inner ring 130b may be substantially uniform around the entire periphery of the semiconductor die module 120. In at least one embodiment, the intermediate structure may be heated as the outer ring 130a and inner ring 130b are pressed onto the first adhesive 160a and second adhesive 160b, respectively. In at least one embodiment, the intermediate structure may be heated to a temperature in a range from 120° C. to 180° C. (e.g., at about 150° C.) as the outer ring 130a and inner ring 130b are pressed onto the first adhesive 160a and second adhesive 160b, respectively.

In at least one embodiment, at the time of attaching the ring structure 130, a viscosity of the first adhesive 160a may be substantially the same as a viscosity of the second adhesive 160b. In at least one embodiment, the pressing force applied to the upper surface of the outer ring 130a may be substantially the same as the pressing force applied to the upper surface of the inner ring 130b. In at least one embodiment, the pressing force may cause the first adhesive 160a to deform at a first deformation rate and cause the second adhesive 160b to deform at a second deformation rate that is substantially the same as the first deformation rate.

The ring structure 130 may then be clamped to the package substrate 110 for a period to allow the first adhesive 160a and the second adhesive 160b to cure and form a secure bond between the package substrate 110 and the ring structure 130. The clamping of the ring structure 130 to the package substrate 110 may be performed, for example, by using a heat clamp module. The heat clamp module may apply a uniform force across the upper surface of the outer ring 130a and the upper surface of the inner ring 130b in the x-direction and the y-direction. The heat clamp module may be applied as the adhesive 160 is cured at a temperature in a range from 120° C. to 180° C. (e.g., at about 150° C.).

Alternatively, the ring structure 130 may be placed on a surface (e.g., a flat surface), and the semiconductor die module 120 (which is mounted on the package substrate 110) may be inverted and inserted down into the ring structure 130. A downward force may then be applied to the package substrate lower passivation layer 110b of the package substrate 110. The ring structure 130 may then be clamped to the package substrate 110 and the adhesive cured so as to bond the package substrate 110 to the ring structure 130.

FIG. 4F illustrates a vertical cross-sectional view of an intermediate structure in which a plurality of solder balls 110c may be formed on the package substrate 110 according to one or more embodiments. The plurality of solder balls 110c may be formed on the lower bonding pads 116a through the openings O110b in the package substrate lower passivation layer 110b. The solder balls 110c may be formed, for example, by an electroplating process. The solder balls 110c may be formed, for example, so as to be located under the ring structure 130 and under the semiconductor die module 120. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate. Formation of the solder balls 110c may complete the formation of the package structure 100.

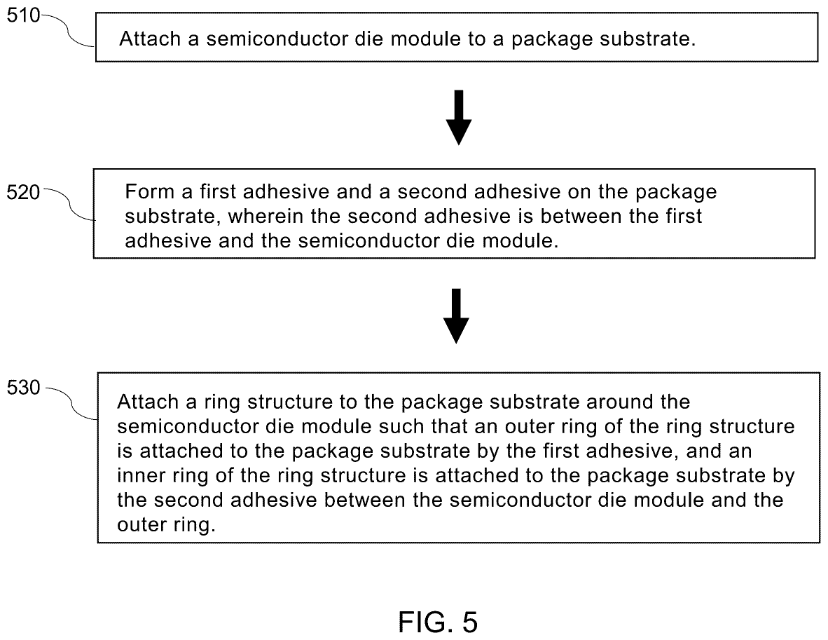

FIG. 5 is a flow chart illustrating a method of making the package structure 100 according to one or more embodiments. Step 510 includes attaching a semiconductor die module to a package substrate. Step 520 includes forming an adhesive on the package substrate including a first adhesive and a second adhesive between the first adhesive and the semiconductor die module. Step 530 includes attaching a ring structure to the package substrate around the semiconductor die module such that an outer ring of the ring structure is attached to the package substrate by the first adhesive, and an inner ring of the ring structure is attached to the package substrate by the second adhesive between the semiconductor die module and the outer ring.

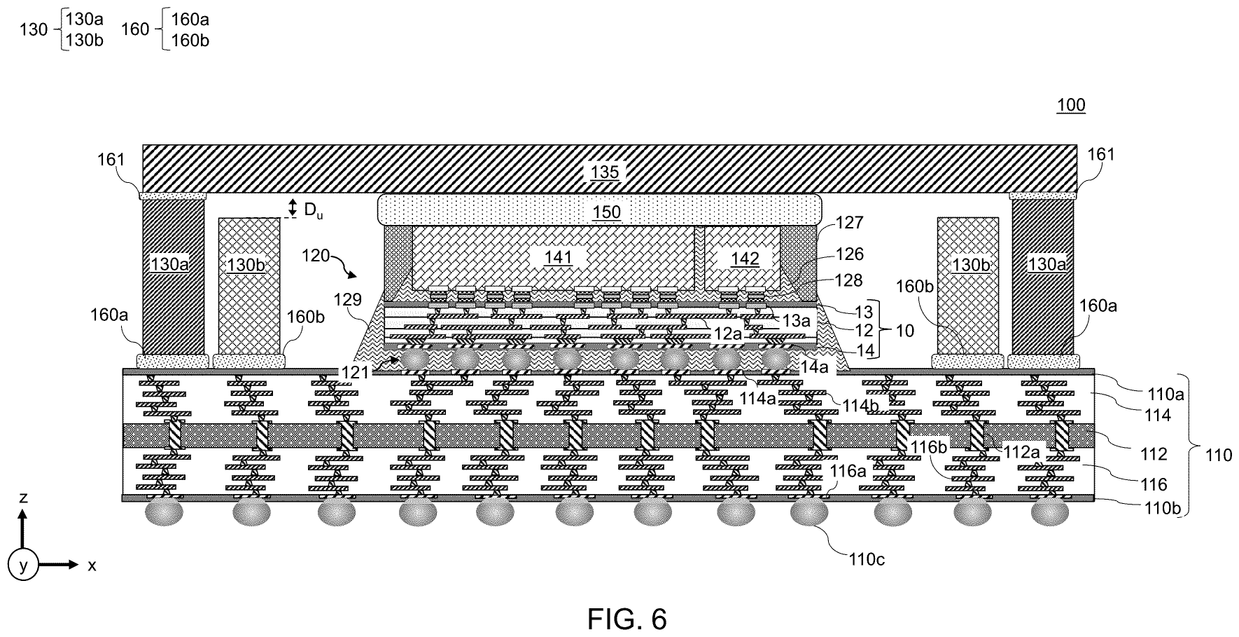

FIG. 6 is a vertical cross-sectional view of the package structure 100 having a first alternative design according to one or more embodiments. As illustrated in FIG. 6, in the first alternative design, the package structure 100 may include a TIM layer 150 on the semiconductor die module 120 and a package lid 135 on the TIM layer 150.

The TIM layer 150 may be formed on the semiconductor die module 120 to dissipate of heat generated during operation of the package structure 100 (e.g., operation of first semiconductor die 141, second semiconductor die 142, and third semiconductor die 143, collectively semiconductor dies 140. The TIM layer 150 may include, for example, a metal TIM layer that may be attached to the semiconductor die module 120, for example, by a thermally conductive adhesive. In particular, the TIM layer 150 may contact the upper surface of the semiconductor dies 140 and the upper surface of the molding material layer 127. The TIM layer 150 may have a low bulk thermal impedance and high thermal conductivity. The bond-line-thickness (BLT) (e.g., a distance between the package lid 135 and the semiconductor die module 120) may be less than about 100 μm, although greater or lesser distances may be used.

The package lid 135 may help to provide rigidity to the package structure 100 and may also help to dissipate heat from the package structure 100. The package lid 135 may be attached to the outer ring 130a by an adhesive 161. The adhesive 161 may be substantially similar to the adhesive 160 (e.g., a silicone-based adhesive, an epoxy-based adhesive, etc.). The package lid 135 may be separated from the upper surface of the inner ring 130b by a distance Du in a range from 0.05 mm to 5.0 mm.

The package lid 135 may contact at least a portion of the TIM layer 150 and may provide a cover for the semiconductor die module 120. In one or more embodiments, the package lid 135 may directly contact an entire upper surface of the TIM layer 150. The package lid 135 may be formed, for example, of metal, ceramic or polymer material. In one or more embodiments, Cu/CuS304/SUS430 may be used as a material for the package lid 135. The package lid 135 may be mold-formed, punched or stamped or a CNC milling tool may be used to fabricate the package lid 135.

The package lid 135 may include a plate portion including a central region that is formed over a central portion of the semiconductor die module 120. In at least one embodiment, the package lid 135 may have a square shape or rectangle shape. Other suitable shapes of the package lid 135 may be within the contemplated scope of disclosure. The outer ring 130a may be attached to the package lid 135 continuously around the entire perimeter of the bottom surface of the package lid 135. The bottom surface of the package lid 135 may be bounded on all sides by the outer ring 130a and may therefore, have a shape that corresponds to (e.g., is substantially the same as) the shape of the outer ring 130a. The package lid 135 may be fixed to the outer ring 130a via a third adhesive 161. The third adhesive 161 may be the same or different from either of first adhesive 160a and/or second adhesive 160b.

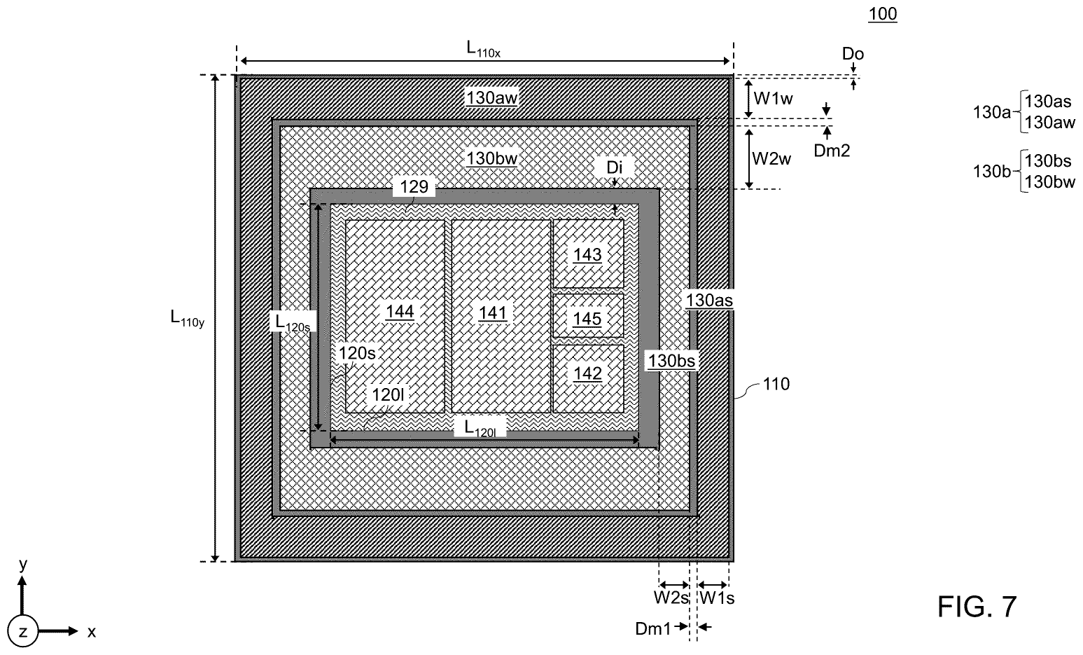

FIG. 7 is a plan view (top down view) of the package structure 100 having a second alternative design according to one or more embodiments. It should be noted that although the inside and outside corners of the outer ring 130a and inner ring 130b appear to be sharp 90° corners in FIG. 7 (and in FIG. 1B), the inside and outside corners of the outer ring 130a and inner ring 130b may be slightly rounded.

As illustrated in FIG. 7, in the second alternative design, the outer ring 130a may include a pair of first sides 130as having a first width W1s and a pair of second sides 130aw having a second width W1w greater than the first width W1s. The inner ring 130b may include a pair of third sides 130bs having a third width W2s and a pair of fourth sides 130bw having a fourth width W2w greater than the third width W2s. The first sides 130as of the outer ring 130a may be located on the third sides 130bs of the inner ring 130b, and the second sides 130aw of the outer ring 130a may be located on the fourth sides 130bw of the inner ring 130b.

In at least one embodiment, the first sides 130as of the outer ring 130a may be separated from the third sides 130bs of the inner ring 130b by a first middle distance Dm1. The second sides 130aw of the outer ring 130a may be separated from the fourth sides 130bw of the inner ring 130b by a second middle distance Dm2. In at least one embodiment, the second middle distance Dm2 may be substantially the same as the first middle distance Dm1. In at least one embodiment, the second middle distance Dm2 may be different than the first middle distance Dm1. In at least one embodiment, at least a portion of the outer ring 130a may contact the inner ring 130b so that the second middle distance Dm2 and/or the first middle distance Dm1 may be zero. In at least one embodiment, the first middle distance Dm1 and/or the second middle distance Dm2 may be less than the outer distance Do.

In at least one embodiment the second width W1w of the second side 130aw of the outer ring 130a may be at least 50% greater than the first width W1s of the first side 130as of the outer ring 130a. In at least one embodiment, the fourth width W2w of the fourth side 130bw of the inner ring 130b may be at least twice the third width W2s of the third side 130bs of the inner ring 130b.

The semiconductor die module 120 may include a first set of semiconductor dies (e.g., SOC dies) including the first semiconductor die 141 and a fourth semiconductor die 144. The semiconductor die module 120 may also include a second set of semiconductor dies (e.g., HBM dies) including the second semiconductor die 142 and third semiconductor die 143. The semiconductor die module 120 may also include one or more dummy dies 145.

The semiconductor die module 120 may have a substantially rectangular shape and include a pair of long sides 1201 having a length L1201 (first semiconductor die module length) and a pair of short sides 120s having a length L120s (second semiconductor die module length) less than the length L1201 of the long sides 1201. The semiconductor die module 120 may have a semiconductor die module length ratio LR120 of length L1201 to length L120s that is greater than 1. In at least one embodiment, semiconductor die module length ratio LR120 of the semiconductor die module 120 may be greater than 1.5. The long side 1201 and short side 120s are indicated in FIG. 7 by a long side of the package underfill 129 and a short side of the package underfill layer 129, respectively. The short side 120s of the semiconductor die module 120 may be adjacent to the third side 130bs of the inner ring 130b, and the long side 1201 of the semiconductor die module 120 may be adjacent to the fourth side 130bw of the inner ring 130b.

As illustrated in FIG. 7, the package substrate 110 may have a length L110x (first package substrate length) in the x-direction and a length L110y (second package substrate length) in the y-direction. The package substrate 110 may have a package substrate length ratio LR110 of length L110x to length L110y that is different than the semiconductor die module length ratio LR120 of the semiconductor die module 120. That is, a shape of the package substrate 110 and a shape of the semiconductor die module 120 may be asymmetrical. In at least one embodiment, the semiconductor die module length ratio LR120 of the semiconductor die module 120 may be greater than the package substrate length ratio LR110 of the package substrate 110. In at least one embodiment, the package substrate length ratio LR110 of the package substrate 110 may be about 1. That is, the package substrate 110 may have a substantially square shape.

In the case of asymmetric shapes of the semiconductor die module 120 and the package substrate 110 (such as in FIG. 7), a width of the outer ring 130a and/or a width of the inner ring 130b may be varied so that the inner distance Di between the inner ring 130b and the semiconductor die module 120 may be substantially uniform around the semiconductor die module 120. Thus, for example, as in FIG. 7, with respect to inner ring 130b, the fourth width W2w in the y-direction may be made greater than the third width W2s in the x-direction, so that the inner distance Di may be substantially uniform around the semiconductor die module 120. Additionally or alternatively, with respect to the outer ring 130a, the second width W2w in the y-direction may be made greater than the first width W2s in the x-direction, so that the inner distance Di may be substantially uniform around the semiconductor die module 120. This may help to manage package warpage in both the x-direction and the y-direction of the package structure 100.

In at least one embodiment, the outer ring 130a may include copper and the inner ring 130b may include Alloy42. Each of the first middle distance Dm1 and the second middle distance Dm2 may be in a range from 0.5 mm to 1.5 mm (e.g., about 1.0 mm). The first width W1s of the first side 130as of the outer ring 130a may be in a range from 1.0 mm to 3.0 mm (e.g., about 2 mm) and the second side 130aw of the outer ring 130a may be in a range from 2 mm to 4 mm (e.g., about 3 mm). The third width W2s of the third side 130bs of the inner ring 130b may be in a range from 1.0 mm to 3.0 mm (e.g., about 2 mm) and the fourth side 130bw of the inner ring 130b may be in a range from 4 mm to 6 mm (e.g., about 5 mm). A combined width of the first side 130as of the outer ring 130a and the third side 130bs of the inner ring 130b (e.g., W1s+W2s) may in a range from 3.0 mm to 7.0 mm (e.g., about 5 mm). A combined width of the second side 130aw of the outer ring 130a and the fourth side 130bw of the inner ring 130b (e.g., W1w+W2w) may in a range from 7.0 mm to 11.0 mm (e.g., about 9 mm).

A distance (e.g., in the x-direction) between inner sidewalls of the first sides 130as of the outer ring 130a may be about 50 mm to 50 mm (e.g., about 55.6 mm). A distance (e.g., in the x-direction) between outer sidewalls of the first sides 130as of the outer ring 130a may be about 55 mm to 65 mm (e.g., about 59.6 mm). A distance (e.g., in the y-direction) between inner sidewalls of the second sides 130aw of the outer ring 130a may be about 48 mm to 58 mm (e.g., about 53.6 mm). A distance (e.g., in the y-direction) between outer sidewalls of the second sides 130aw of the outer ring 130a may be about 55 mm to 65 mm (e.g., about 59.6 mm).

A distance (e.g., in the x-direction) between inner sidewalls of the third sides 130bs of the inner ring 130b may be about 45 mm to 55 mm (e.g., about 49.6 mm). A distance (e.g., in the x-direction) between outer sidewalls of the third sides 130bs of the inner ring 130b may be about 48 mm to 58 mm (e.g., about 53.6 mm). A distance (e.g., in the y-direction) between inner sidewalls of the fourth sides 130bw of the inner ring 130b may be about 35 mm to 45 mm (e.g., about 41.6 mm). A distance (e.g., in the y-direction) between outer sidewalls of the fourth sides 130bw of the inner ring 130b may be about 45 mm to 55 mm (e.g., about 51.6 mm).

In at least one embodiment, a size of the inner ring 130b may decrease as the first middle distance Dm1 and second middle distance Dm2 of the space S2 between the outer ring 130a and the inner ring 130b increase. Thus, for example, the first width W1s of the first side 130as of the outer ring 130a may be about 2 mm and the second width W1w of the second side 130aw of the outer ring 130a may be about 3 mm. If there is no space S2 (i.e., Dm1=Dm2=0), then the third width W2s of the third side 130bs of the inner ring 130b may be about 2.9 mm and the fourth width W2w of the fourth side 130bw of the inner ring 130b may be about 5.9 mm. However, if the space S2 is present and Dₘ=1 mm, then the third width W2s of the third side 130bs of the inner ring 130b may be about 2 mm and the fourth width W2w of the fourth side 130bw of the inner ring 130b may be about 5 mm.

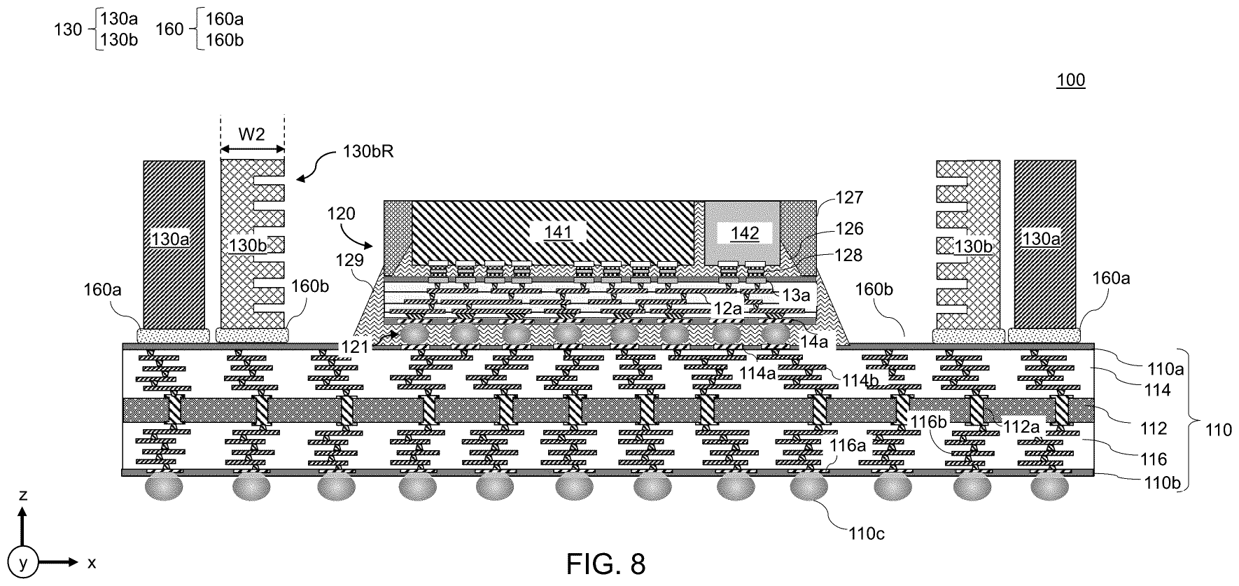

FIG. 8 is a vertical cross-sectional view of the package structure 100 having a third alternative design according to one or more embodiments. As illustrated in FIG. 8, in the third alternative design, the inner ring 130b may include a conditioned surface. The conditioned surface may be conditioned, for example, by milling, etching, etc. The conditioned surface may be conditioned so as to increase heat dissipation by the inner ring 130b. The conditioned surface may be conditioned, for example, to increase a surface area of the inner ring 130b.

In at least one embodiment, the conditioned surface may include a plurality of fins 130bF (also referred to as a plurality of ribs 130bF). The plurality of fins 130bF may increase the surface area of the inner ring 130b and thereby assist with heat dissipation by the inner ring 130b. A width (in the x-direction) of the plurality of fins 130bF may be in a range from 5% to 40% of the total width W2 of the inner ring 130b.

As illustrated in FIG. 8, the conditioned surface including the plurality of fins 130bF may be formed on the inner sidewall of the inner ring 130b. The conditioned surface including a plurality of fins 130bF may be alternatively or additionally formed on the outer sidewall of the inner ring 130b and the upper surface of the inner ring 130b. The conditioned surface including a plurality of fins 130bF may be formed, for example, by punching, stamping or milling using a CNC milling tool.

FIG. 9 is a vertical cross-sectional view of the package structure 100 having a fourth alternative design according to one or more embodiments. As illustrated in FIG. 9, in the fourth alternative design of the package structure, the inner ring 130b may be attached to the package substrate 110 beneath the upper surface of the package substrate upper dielectric layer 114. In particular, at least a part of the inner ring 130b may be located in an opening O114 (recessed portion) in the package substrate upper dielectric layer 114. The fourth alternative design may further assist in dissipating heat in the package structure 100.

In at least one embodiment, a bottom of the opening O114 may be defined by an upper surface of the core 112 of the package substrate 110. In that case, the inner ring 130b may be attached by the second adhesive 160b to the upper surface of the core 112. In at least one embodiment, the opening O114 does not completely penetrate the package substrate upper dielectric layer 114. In that case, the inner ring 130b may be attached to an interior surface of the package substrate upper dielectric layer 114.

Referring now to FIGS. 1A-9, a package structure 100 may include a package substrate 110, a semiconductor die module 120 on the package substrate 110, a first adhesive 160a and a second adhesive 160b on the package substrate, wherein the second adhesive 160b is between the first adhesive 160a and the semiconductor die module 120, and a ring structure 130 on the package substrate 110 around the semiconductor die module 120, wherein the ring structure 130 may include an outer ring 130a attached to the package substrate 110 by the first adhesive 160a, and an inner ring 130b attached to the package substrate 110 by the second adhesive 160b between the semiconductor die module 120 and the outer ring 130a.

In one embodiment, the outer ring 130a may have a first thickness H1 and the inner ring 130b may have a second thickness H2 less than or equal to the first thickness H1, which may be in a range from 0.1 mm to 10 mm, and a thickness ratio of the second thickness H2 to the first thickness H1 may be in a range from 0.5 to 1.0. In one embodiment, the outer ring 130a may have a first width W1 and the inner ring 130b may have a second width W2 greater than the first width W1, which may be in a range from 0.5 mm to 10 mm, and a width ratio of the second width to the first width W1 may be in a range from 0.8 to 1.2. In one embodiment, the outer ring 130a may have a first coefficient of thermal expansion (CTE) and the inner ring 130b may include a second material different than the first material and have a second CTE greater than the first CTE. In one embodiment, the outer ring 130a may have a first coefficient of thermal expansion (CTE) and the inner ring 130b may have a second CTE, the first CTE may be in a range from 3 ppm/° C. to 20 ppm/° C., and a CTE ratio of the second CTE to the first CTE may be in a range from 0.2 to 5.0. In one embodiment, the outer ring 130a may include a first material and the inner ring 130b may include a second material different than the first material. In one embodiment, the outer ring 130a may be located around an outer periphery of the package substrate 110, and an outer distance Do between the outer ring 130a and an edge of the package substrate 110 may be greater than a middle distance Dm between the outer ring 130a and the inner ring 130b. The outer distance Do may be in a range of 0.1 mm to 1 mm. The middle distance Dm may be less than or equal to 3 mm. In one embodiment, an inner distance Di between the inner ring 130b and the semiconductor die module 120 may be greater than the outer distance Do between the outer ring and the edge of the package substrate, and may be in a range from 1 mm to 5 mm. In one embodiment, the outer ring 130a may have a first side 130as having a first width W1s and a second side 130aw having a second width greater than the first width W1s, and the inner ring 130b may have a third side 130bs having a third width and a fourth side 130bw having a fourth width greater than the third width. In one embodiment, the first side 130as of the outer ring 130a may be located on the third side 130bs of the inner ring 130b, and the second side 130aw of the outer ring 130a may be located on the fourth side 130bw of the inner ring 130b. In one embodiment, the first side 130as of the outer ring 130a may be separated from the third side 130bs of the inner ring 130b by a first middle distance Dm1 and the second side 130aw of the outer ring 130a may be separated from the fourth side 130bw of the inner ring 130b by a second middle distance Dm2 substantially the same as the first middle distance Dm1. In one embodiment, the second width W1w of the second side 130aw of the outer ring 130a may be at least 50% greater than the first width W1s of the first side 130as of the outer ring 130a, and the fourth width W2w of the fourth side 130bw of the inner ring 130b may be at least twice the third width W2s of the third side 130bs of the inner ring 130b. In one embodiment, the semiconductor die module 120 may have a long side 1201 and a short side 120s having a length less than the long side 1201, the short side 120s of the semiconductor die module 120 may be adjacent to the third side 130bs of the inner ring 130b, and the long side 1201 of the semiconductor die module 120 may be adjacent to the fourth side 130bw of the inner ring 130b. In one embodiment, the package structure 100 may further include a package lid 135 mounted on the outer ring 130a and covering the semiconductor die module 120, and a thermal interface material (TIM) layer 150 between the package lid 135 and the semiconductor die module 120. In one embodiment, an upper surface of the inner ring 130b may be separated from a bottom surface of the package lid 135. The inner ring 130b may include a conditioned surface including a plurality of fins 130bR. The package substrate 110 may include a recessed portion O114 and the inner ring 130b is attached to the package substrate 110 in the recessed portion O114.

Referring again to FIGS. 1A-9, a method of making a package structure 100 may include attaching a semiconductor die module 120 on a package substrate 110, forming a first adhesive 160a and a second adhesive 160b on the package substrate 110, wherein the second adhesive 160b is between the first adhesive 160a and the semiconductor die module 120, and attaching a ring structure 130 to the package substrate 110 around the semiconductor die module 120 such that an outer ring 130a of the ring structure 130 may be attached to the package substrate 110 by the first adhesive 160a, and an inner ring 130b of the ring structure 130 may be attached to the package substrate 110 by the second adhesive 160b between the semiconductor die module 120 and the outer ring 130a. In one embodiment, the attaching of the ring structure 130 to the package substrate 110 may include attaching the inner ring 130b to the package substrate 110 such that an outer distance Do between the outer ring 130a and an edge of the package substrate 110 is greater than a middle distance Dₘ between the outer ring 130a and the inner ring 130b. The inner distance between the inner ring 130b and the semiconductor die module 120 may be in a range from 1 mm to 5 mm. The middle distance Bm between the outer ring 130a and the inner ring 130b may be less than or equal to 3 mm. In one embodiment, the attaching of the ring structure 130 to the package substrate 110 may include attaching the outer ring 130a to the package substrate 110 such that an inner distance Di between the inner ring 130b and the semiconductor die module 120 is greater than the outer distance Do between the outer ring 130a and the edge of the package substrate 110. In one embodiment, the attaching of the ring structure 130 to the package substrate 110 may include attaching the outer ring 130a to the package substrate 110 such that the outer ring 130a may be located around an outer periphery of the package substrate 110 and an outer distance Do between the outer ring 130a and an edge of the package substrate 110 may be in the range from 0.1 mm to 1 mm. In one embodiment, the method may further include forming a thermal interface material (TIM) layer 150 on the semiconductor die module 120, and attaching a package lid 135 to the outer ring 130a and on the TIM layer 150.

Referring again to FIGS. 1A-9, a package structure 100 may include a package substrate 110 having a first package substrate length L110x in a first direction and a second package substrate length L110y in a second direction perpendicular to the first direction, and having a package substrate length ratio of the first package substrate length L110x to the second package substrate length L110y, a semiconductor die module 120 including a first semiconductor die module length L120x in the first direction and a second semiconductor die module length L120y in the second direction, and having a semiconductor die module length ratio of the first semiconductor die module length L120x to the second semiconductor die module length L120y greater than the package substrate length ratio, a first adhesive 160a and a second adhesive 160b on the package substrate 110, wherein the second adhesive 160b is between the first adhesive 160a and the semiconductor die module 120, and a ring structure 130 attached to the package substrate 110 around the semiconductor die module 120. The ring structure 130 may include an outer ring 130a attached to the package substrate 110 by the first adhesive 160a and having a first width W1s in the first direction and a second width W1w greater than the first width W1s in the second direction, and an inner ring 130b attached to the package substrate 110 by the second adhesive 160b and having a third width W2s in the first direction and a fourth width W2w greater than the third width W2s in the second direction.

Referring again to FIGS. 1A-9, a package structure 100 may include a package substrate 110, a semiconductor die module 120 including a system-on-chip (SoC) die and a high bandwidth memory (HBM) die on the package substrate 110, an adhesive on the package substrate 110 having Young's modulus in a range from 0.1 GPa to 10 GPa, wherein the adhesive may include a first adhesive 160a and a second adhesive 160b between the first adhesive 160a and the semiconductor die module 120, and a ring structure 130 attached to the package substrate 110 around the semiconductor die module 120. The ring structure 130 may include an outer ring 130a attached to the package substrate 110 by the first adhesive 160a and including a first material and having a first coefficient of thermal expansion (CTE) in a range from 3 ppm/° C. to 20 ppm/° C., wherein an outer distance Do between the outer ring 130a and an edge of the package substrate 110 may be in a range from 0.1 mm to 1 mm, and an inner ring 130b attached to the package substrate 110 by the second adhesive 160b between the semiconductor die module 120 and the outer ring 130a, wherein the inner ring 130b may include a second material different than the first material and may have a second CTE greater than the first CTE, a middle distance Dm between the outer ring 130a and the inner ring 130b may be less than or equal to 3 mm, and an inner distance Di between the inner ring 130b and the semiconductor die module 120 may be in a range from 1 mm to 5 mm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a semiconductor die module on the package substrate;
a first adhesive and a second adhesive on the package substrate, wherein the second adhesive is between the first adhesive and the semiconductor die module; and
a ring structure on the package substrate around the semiconductor die module, wherein the ring structure comprises an outer ring attached to the package substrate by the first adhesive, and an inner ring attached to the package substrate by the second adhesive between the semiconductor die module and the outer ring.

2. The package structure of claim 1, wherein the outer ring has a first thickness and the inner ring has a second thickness less than or equal to the first thickness.

3. The package structure of claim 1, wherein the outer ring has a first width and the inner ring has a second width greater than the first width.

4. The package structure of claim 1, wherein the outer ring includes a first material and has a first coefficient of thermal expansion (CTE) and the inner ring includes a second material different than the first material and has a second CTE greater than the first CTE.

5. The package structure of claim 1, wherein the outer ring is located around an outer periphery of the package substrate and an outer distance between the outer ring and an edge of the package substrate is greater than a middle distance between the outer ring and the inner ring.

6. The package structure of claim 1, wherein an inner distance between the inner ring and the semiconductor die module is greater than the outer distance between the outer ring and the edge of the package substrate.

7. The package structure of claim 1, wherein the outer ring has a first side having a first width and a second side having a second width greater than the first width, and the inner ring has a third side having a third width and a fourth side having a fourth width greater than the third width.

8. The package structure of claim 7, wherein the first side of the outer ring is located on the third side of the inner ring, and the second side of the outer ring is located on the fourth side of the inner ring.

9. The package structure of claim 8, wherein the first side of the outer ring is separated from the third side of the inner ring by a first middle distance and the second side of the outer ring is separated from the fourth side of the inner ring by a second middle distance substantially the same as the first middle distance.

10. The package structure of claim 7, wherein the second width of the second side of the outer ring is at least 50% greater than the first width of the first side of the outer ring, and the fourth width of the fourth side of the inner ring is at least twice the third width of the third side of the inner ring.

11. The package structure of claim 7, wherein the semiconductor die module has a long side and a short side having a length less than the long side, the short side of the semiconductor die module is adjacent to the third side of the inner ring, and the long side of the semiconductor die module is adjacent to the fourth side of the inner ring.

12. The package structure of claim 1, further comprising:
a package lid mounted on the outer ring and covering the semiconductor die module; and
a thermal interface material (TIM) layer between the package lid and the semiconductor die module.

13. The package structure of claim 12, wherein an upper surface of the inner ring is separated from a bottom surface of the package lid.

14. The package structure of claim 1, wherein the inner ring includes a conditioned surface including a plurality of fins.

15. The package structure of claim 1, wherein the package substrate includes a recessed portion and the inner ring is attached to the package substrate in the recessed portion.

16. A method of making a package structure, the method comprising:
attaching a semiconductor die module on a package substrate;
forming a first adhesive and a second adhesive on the package substrate, wherein the second substrate is between the first adhesive and the semiconductor die module; and
attaching a ring structure to the package substrate around the semiconductor die module such that an outer ring of the ring structure is attached to the package substrate by the first adhesive, and an inner ring of the ring structure is attached to the package substrate by the second adhesive between the semiconductor die module and the outer ring.

17. The method of claim 16, wherein the attaching of the ring structure to the package substrate comprises attaching the inner ring to the package substrate such that an outer distance between the outer ring and an edge of the package substrate is greater than a middle distance between the outer ring and the inner ring.

18. The method of claim 17, wherein the attaching of the ring structure to the package substrate comprises attaching the outer ring to the package substrate such that an inner distance between the inner ring and the semiconductor die module is greater than the outer distance between the outer ring and the edge of the package substrate.

19. The method of claim 16, further comprising:
forming a thermal interface material (TIM) layer on the semiconductor die module; and
attaching a package lid to the outer ring and on the TIM layer.

20. A package structure, comprising:
a package substrate having a first package substrate length in a first direction and a second package substrate length in a second direction perpendicular to the first direction, and having a package substrate length ratio of the first package substrate length to the second package substrate length;
a semiconductor die module having a first semiconductor die module length in the first direction and a second semiconductor die module length in the second direction, and having a semiconductor die module length ratio of the first semiconductor die module length to the second semiconductor die module length greater than the package substrate length ratio;
a first adhesive and a second adhesive on the package substrate, wherein the second adhesive is between the first adhesive and the semiconductor die module; and
a ring structure attached to the package substrate around the semiconductor die module, wherein the ring structure comprises:
an outer ring attached to the package substrate by the first adhesive and having a first width in the first direction and a second width greater than the first width in the second direction; and
an inner ring attached to the package substrate by the second adhesive and having a third width in the first direction and a fourth width greater than the third width in the second direction.
